(19) United States
(12) Patent Application Publication
(10) Pub. No.: US 2017/0373232 A1
(43) Pub. Date: Dec. 28, 2017

(54) Methods for Buffered Coating of Nanostructures

(71) Applicant: Nanosys, Inc., Milpitas, CA (US)

(72) Inventors: Shihai KAN, Milpitas, CA (US); Jay YAMANAGA, Milpitas, CA (US); Charles HOTZ, Milpitas, CA (US); Christian IPPEN, Milpitas, CA (US); Wenzhuo GUO, Milpitas, CA (US)

(73) Assignee: Nanosys, Inc., Milpitas, CA (US)

(21) Appl. No.: 15/629,031

(22) Filed: Jun. 21, 2017

Related U.S. Application Data
(60) Provisional application No. 62/354,845, filed on Jun. 27, 2016.

(51) Int. Cl. H01L 33/50; H01L 51/56; H01L 33/58; H01L 51/52; H01L 27/32; B82Y 40/00; B82Y 20/00; G02F 1/1333

(52) U.S. Cl. CPC H01L 33/507; H01L 51/5262; H01L 51/56; H01L 27/322; H01L 33/58; Y10S 977/774; H01L 2933/0041; B82Y 20/00; G02F 1/1333; B82Y 40/00; Y10S 977/888; Y10S 977/892; Y10S 977/95; Y10S 977/952; H01L 2251/5369

(57) ABSTRACT

Embodiments of a population of buffered barrier layer coated nanostructures and a method of making the nanostructures are described. Each of the buffered barrier layer coated nanostructures includes a nanostructure, an optically transparent buffer layer disposed on the nanostructure, and an optically transparent buffered barrier layer disposed on the buffer layer. The buffered barrier layer is configured to provide a spacing between adjacent nanostructures in the population of buffered barrier layer coated nanostructures to reduce aggregation of the adjacent nanostructures. The method for making the nanostructures includes forming a solution of reverse micro-micelles using surfactants, incorporating nanostructures into the reverse micro-micelles, and incorporating a buffer agent into the reverse micro-micelles. The method further includes individually coating the nanostructures with a buffered barrier layer and isolating the buffered barrier layer coated nanostructures with the surfactants of the reverse micro-micelles disposed on the barrier layer.

### CROSS REFERENCE TO RELATED APPLICATIONS

This application incorporates by reference in their entirety U.S. Provisional Appl. No. 62/354,845, filed Jun. 27, 2016.

### BACKGROUND OF THE INVENTION

### Field

The present invention relates to display devices including highly luminescent nanostructures comprising a core-shell structure.

### Background

Nanostructures (NSs) have the unique ability to emit light at a single spectral peak with narrow line width, creating highly saturated colors. It is possible to tune the emission wavelength based on the size of the NSs. This ability to tune the emission wavelength enables display engineers to custom engineer a spectrum of light to maximize both the efficiency and color performance of the display.

The size-dependent properties of NSs are used to produce a NS film. The NS film may be used as a color down conversion layer in display devices. The use of a color down conversion layer in emissive displays can improve the system efficiency by down-converting white light to a more reddish light, greenish light, or both before the light passes through a color filter. This use of a color down conversion layer may reduce loss of light energy due to filtering.

NSs may be used as the conversion material due to their broad absorption and narrow emission spectra. Because the density of NSs required for such application is very high in a very thin color down conversion layer of about 3 μm-6 μm, NSs prepared using current methods suffer from quenching of their optical properties. As a result, low quantum yield (QY) is obtained when the NSs are closely packed next to each other in a thin NS film. As such, current NS-based devices using NS films as color down conversion layers suffer from low quantum yield (QY).

### SUMMARY

Accordingly, there is need to increase the quality of NS-based devices. Disclosed herein are embodiments that overcome the above mentioned limitations of display devices.

According to an embodiment, the invention provides a population of buffered barrier layer coated nanostructures including a nanostructure, an optically transparent buffer layer disposed on the nanostructure, and an optically transparent buffered barrier layer disposed on the buffer layer. The optically transparent buffered barrier layer is configured to provide a spacing between adjacent nanostructures in the population of buffered barrier layer coated nanostructures to reduce aggregation of the adjacent nanostructures.

According to an embodiment, the optically transparent buffer layer comprises an oxide. According to an embodiment, the optically transparent buffer layer comprises a metal oxide. According to an embodiment, the optically transparent buffer layer comprises transparent conductive oxides AZO, GZO, IZO, FTO, ITO, or a combination thereof. According to an embodiment, the optically transparent buffered barrier layer is hydrophobic. According to an embodiment, the spacing is equal or greater than a Forster radius between adjacent buffered barrier layer coated nanostructures. According to an embodiment, the nanostructure comprises a core-shell structure having a core and a shell surrounding the core. According to an embodiment, the core comprises a first material, the shell comprises a second material, the optically transparent buffer layer comprises a third material, the optically transparent buffered barrier layer comprises a fourth material, and the first, second, and third materials are different from each other. According to an embodiment, the optically transparent buffered barrier layer comprises an oxide. According to an embodiment, the optically transparent buffered barrier layer comprises silicon dioxide. According to an embodiment, the population of buffered barrier layer coated nanostructures further includes surfactants or ligands bonded to the optically transparent buffered barrier layer. According to an embodiment, the population of buffered barrier layer coated nanostructures has a quantum yield between about 50% to about 70%. According to an embodiment, the population of buffered barrier layer coated nanostructures has a quantum yield between about 55% to about 65%. According to an embodiment, the population of buffered barrier layer coated nanostructures has a quantum yield between about 65% to about 80%. According to an embodiment, a buffered barrier layer coated nanostructure in the population of buffered barrier layer coated nanostructures has an average size ranging from about 20 nm and to about 40 nm in diameter. According to an embodiment, a buffered barrier layer coated nanostructure in the population of buffered barrier layer coated nanostructures has an average size ranging from about 25 nm and to about 35 nm in diameter. According to an embodiment, the optically transparent buffered barrier layer has a thickness ranging from about 8 nm and to about 20 nm in diameter. According to an embodiment, the population of buffered barrier layer coated nanostructures are a population of buffered barrier layer coated quantum dots.

According to an embodiment, a method of making the population of buffered barrier layer coated nanostructures includes forming a solution of reverse micro-micelles comprising surfactants, incorporating nanostructures into the reverse micro-micelles, and incorporating a buffer agent into the reverse micro-micelles. The method further includes individually coating the nanostructures with a buffered barrier layer to form the buffered barrier layer coated nanostructures and isolating the buffered barrier layer coated nanostructures with surfactants of the reverse micro-micelles disposed on the barrier layer.

According to an embodiment, the incorporating of the nanostructures into the reverse micro-micelles includes forming a first mixture of the nanostructures and the solution of reverse micelles. According to an embodiment, the incorporating of the buffer agent into the reverse micro-micelles includes forming a second mixture of the buffer agent and the first mixture. According to an embodiment, the individually coating of the nanostructures with a buffered barrier layer includes forming a third mixture of a precursor and the second mixture and forming a fourth mixture of a catalyst and the third mixture. According to an embodiment, the isolating of the buffered barrier layer coated nanostructures includes heating the fourth mixture at or below a temperature of about 50° C. under vacuum. According to an embodiment, the buffer agent comprises an organic or an inorganic material. According to an embodiment, the buffer agent comprises a metal salt. According to an embodiment, the method further includes forming a buffer layer in substantial contact with the nanostructures incorporated into the reverse micro-micelles. According to an embodiment, the buffer layer comprises an oxide. According to an embodiment, the buffer layer comprises a metal oxide.

According to an embodiment, the invention provides a nanostructure film including the population of buffered barrier layer coated nanostructures and a matrix material comprising the population of buffered barrier layer coated nanostructures.

According to an embodiment, the invention provides a display device comprising a layer that emits radiation, a film layer comprising a population of buffered barrier layer nanostructures disposed on the radiation emitting layer, and an optical element disposed on the film layer.

According to an embodiment, the radiation emitting layer, the film layer, and the optical element are part of a pixel unit of the display device. According to an embodiment, the optical element is a color filter.

According to an embodiment, the invention provides a light emitting diode (LED) device comprising a light source unit, a film layer comprising a population of buffered barrier layer nanostructures disposed on the light source unit, and an optical element disposed on the film layer.

According to an embodiment, a method of making the population of buffered barrier layer coated nanostructures comprises forming a solution of reverse micro-micelles using surfactants, incorporating nanostructures into the reverse micro-micelles, incorporating a buffer agent into the reverse micro-micelles, individually coating the nanostructures with a buffered barrier layer to form the buffered barrier layer coated nanostructures, and performing an acid etch treatment of the buffered barrier layer coated nanostructures.

According to an embodiment, the method further comprising isolating the buffered barrier layer coated nanostructures with the surfactants of the reverse micro-micelles disposed on the barrier layer after the performing the acid etch treatment. According to an embodiment, the incorporating of the nanostructures into the reverse micro-micelles comprises forming a first mixture of the nanostructures and the solution of reverse micelles. According to an embodiment, the incorporating of the buffer agent into the reverse micro-micelles comprises forming a second mixture of the buffer agent and the first mixture. According to an embodiment, the individually coating of the nanostructures with a buffered barrier layer includes forming a third mixture of a precursor and the second mixture and forming a fourth mixture of a catalyst and the third mixture. According to an embodiment, the performing of the acid etch treatment of the buffered barrier layer nanostructures comprises forming a sixth mixture of an acid and the fourth mixture. According to an embodiment, the performing of the acid etch treatment of the buffered barrier layer nanostructures comprises selectively removing the catalyst and forming a sixth mixture of an acid and the fourth mixture. According to an embodiment, the acid comprises acetic acid, hydrochloric acid, nitric acid, or a fatty acid.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present embodiments and, together with the description, further serve to explain the principles of the present embodiments and to enable a person skilled in the relevant art(s) to make and use the present embodiments.

FIG. 1 illustrates a cross-sectional structure of a buffered barrier layer coated NS, according to an embodiment.

FIGS. 2A-2E illustrate a process of forming buffered barrier layer coated NSs, according to an embodiment.

FIGS. 3A-3E illustrate example optical characteristics of uncoated red InP based NSs, according to an embodiment.

FIGS. 4A-4C illustrate transmission electron micrographs of red InP based NSs, according to an embodiment.

FIGS. 5A-5B illustrate transmission electron micrographs of green InP based NSs, according to an embodiment.

FIGS. 6A-6B illustrate transmission electron micrographs of green InP based NSs, according to an embodiment.

FIG. 7 is a graph showing the atomic ratio of Zn/(S+Se) for uncoated and coated NSs.

FIGS. 8A-8O illustrate example optical characteristics of InP based NSs, according to an embodiment.

FIG. 9 is a flowchart for forming buffered barrier layer coated NSs, according to an embodiment.

FIG. 10 illustrates a NS film including buffered barrier layer coated NSs, according to an embodiment.

FIG. 11 illustrates a cross-sectional view of a display panel of a display device, according to an embodiment.

FIG. 12 illustrates a schematic of an exploded cross-sectional view of a NS film based pixel unit of a display device, according to an embodiment.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number. Unless otherwise indicated, the drawings provided throughout the disclosure should not be interpreted as to-scale drawings.

### DETAILED DESCRIPTION OF THE INVENTION

Although specific configurations and arrangements may be discussed, it should be understood that this is done for illustrative purposes only. A person skilled in the pertinent art will recognize that other configurations and arrangements can be used without departing from the spirit and scope of the present invention. It will be apparent to a person skilled in the pertinent art that this invention can also be employed in a variety of other applications beyond those specifically mentioned herein.

It is noted that references in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

All numbers in this description indicating amounts, ratios of materials, physical properties of materials, and/or use are to be understood as modified by the word “about,” except as otherwise explicitly indicated.

The term “about” as used herein indicates the value of a given quantity varies by ±10% of the value. For example, “about 100 nm” encompasses a range of sizes from 90 nm to 110 nm, inclusive.

The term “forming a reaction mixture” or “forming a mixture” as used herein refers to combining at least two components in a container under conditions suitable for the components to react with one another and form a third component.

The term “nanostructure” as used herein refers to a structure having at least one region or characteristic dimension with a dimension of less than about 500 nm. In some embodiments, the nanostructure has a dimension of less than about 200 nm, less than about 100 nm, less than about 50 nm, less than about 20 nm, or less than about 10 nm. Typically, the region or characteristic dimension will be along the smallest axis of the structure. Examples of such structures include nanowires, nanorods, nanotubes, branched nanostructures, nanotetrapods, tripods, bipods, nanocrystals, nanodots, QDs, nanoparticles, and the like. Nanostructures can be, e.g., substantially crystalline, substantially monocrystalline, polycrystalline, amorphous, or a combination thereof. In some embodiments, each of the three dimensions of the nanostructure has a dimension of less than about 500 nm, less than about 200 nm, less than about 100 nm, less than about 50 nm, less than about 20 nm, or less than about 10 nm.

The term “QD” or “nanocrystal” as used herein refers to nanostructures that are substantially monocrystalline. A nanocrystal has at least one region or characteristic dimension with a dimension of less than about 500 nm, and down to the order of less than about 1 nm. The terms “nanocrystal,” “QD,” “nanodot,” and “dot,” are readily understood by the ordinarily skilled artisan to represent like structures and are used herein interchangeably. The present invention also encompasses the use of polycrystalline or amorphous nanocrystals.

The term “heterostructure” when used with reference to nanostructures refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanowire, or the center of a nanocrystal, for example. A shell can but need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanowire. Different regions within a heterostructure can comprise entirely different materials, or the different regions can comprise a base material (e.g., silicon) having different dopants or different concentrations of the same dopant.

As used herein, the term “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The terms “crystalline” or “substantially crystalline,” when used with respect to nanostructures, refer to the fact that the nanostructures typically exhibit long-range ordering across one or more dimensions of the structure. It will be understood by one of skill in the art that the term “long range ordering” will depend on the absolute size of the specific nanostructures, as ordering for a single crystal cannot extend beyond the boundaries of the crystal. In this case, “long-range ordering” will mean substantial order across at least the majority of the dimension of the nanostructure. In some instances, a nanostructure can bear an oxide or other coating, or can be comprised of a core and at least one shell. In such instances it will be appreciated that the oxide, shell(s), or other coating can but need not exhibit such ordering (e.g. it can be amorphous, polycrystalline, or otherwise). In such instances, the phrase “crystalline,” “substantially crystalline,” “substantially monocrystalline,” or “monocrystalline” refers to the central core of the nanostructure (excluding the coating layers or shells). The terms “crystalline” or “substantially crystalline” as used herein are intended to also encompass structures comprising various defects, stacking faults, atomic substitutions, and the like, as long as the structure exhibits substantial long range ordering (e.g., order over at least about 80% of the length of at least one axis of the nanostructure or its core). In addition, it will be appreciated that the interface between a core and the outside of a nanostructure or between a core and an adjacent shell or between a shell and a second adjacent shell may contain non-crystalline regions and may even be amorphous. This does not prevent the nanostructure from being crystalline or substantially crystalline as defined herein.

The term “monocrystalline” when used with respect to a nanostructure indicates that the nanostructure is substantially crystalline and comprises substantially a single crystal. When used with respect to a nanostructure heterostructure comprising a core and one or more shells, “monocrystalline” indicates that the core is substantially crystalline and comprises substantially a single crystal.

The term “ligand” as used herein refers to a molecule capable of interacting (whether weakly or strongly) with one or more faces of a nanostructure, e.g., through covalent, ionic, van der Waals, or other molecular interactions with the surface of the nanostructure.

The term “native ligand” as used herein refers to the ligands that are bonded on an outer surface of an outermost shell of a nanostructure.

The term “quantum yield” (QY) as used herein refers to the ratio of photons emitted to photons absorbed, e.g., by a nanostructure or population of nanostructures. As known in the art, quantum yield is typically determined by a comparative method using well-characterized standard samples with known quantum yield values.

The term “primary emission peak wavelength” as used herein refers to the wavelength at which the emission spectrum exhibits the highest intensity.

The term “full width at half-maximum” (FWHM) as used herein refers to a measure of the size distribution of NSs. The emission spectra of NSs generally have the shape of a Gaussian curve. The width of the Gaussian curve is defined as the FWHM and gives an idea of the size distribution of the NSs. A smaller FWHM corresponds to a narrower size distribution of the NSs. FWHM is also dependent upon the emission wavelength maximum.

The term Forster radius used herein is also referred as Forster distance in the art.

### An Example Embodiment of a Buffered Barrier Layer Coated Nanostructure

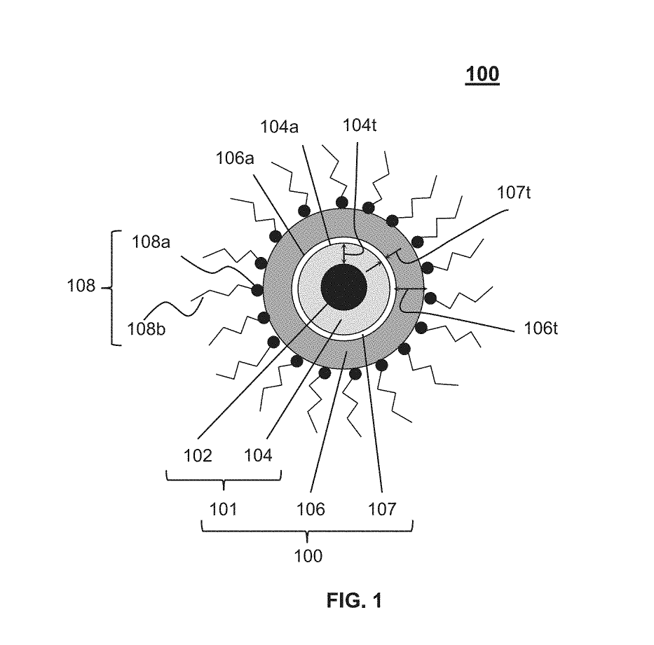

FIG. 1 illustrates a cross-sectional structure of a buffered barrier layer coated NS 100, according to an embodiment. Buffered barrier layer coated NS 100 includes a NS 101 and a buffered barrier layer 106. NS 101 includes a core 102 and a shell 104. Core 102 includes a semiconducting material that emits light upon absorption of higher energies. Examples of the semiconducting material for core 102 include indium phosphide (InP), cadmium selenide (CdSe), zinc sulfide (ZnS), lead sulfide (PbS), indium arsenide (InAs), indium gallium phosphide, (InGaP), cadmium zinc selenide (CdZnSe), zinc selenide (ZnSe) and cadmium telluride (CdTe). Any other II-VI, III-V, tertiary, or quaternary semiconductor structures that exhibit a direct band gap may be used as well. In an embodiment, core 102 may also include one or more dopants such as metals, alloys, to provide some examples. Examples of metal dopant may include, but not limited to, zinc (Zn), Copper (Cu), aluminum (Al), platinum (Pt), chrome (Cr), tungsten (W), palladium (Pd), or a combination thereof. The presence of one or more dopants in core 102 may improve structural and optical stability and QY of NS 101 compared to undoped NSs.

Core 102 may have a size of less than 20 nm in diameter, according to an embodiment. In another embodiment, core 102 may have a size between about 1 nm and about 5 nm in diameter. The ability to tailor the size of core 102, and consequently the size of NS 101 in the nanometer range enables photoemission coverage in the entire optical spectrum. In general, the larger NSs emit light towards the red end of the spectrum, while smaller NSs emit light towards the blue end of the spectrum. This effect arises as larger NSs have energy levels that are more closely spaced than the smaller NSs. This allows the NS to absorb photons containing less energy, i.e. those closer to the red end of the spectrum.

Shell 104 surrounds core 102 and is disposed on outer surface of core 102. Shell 104 may include cadmium sulfide (CdS), cadmium selenide (CdSe), zinc cadmium sulfide (ZnCdS), zinc selenide sulfide (ZnSeS), zinc sulfide (ZnS), zinc selenide (ZnSe), zinc telluride (ZnTe), zinc telluride sulfide (ZnTeS), zinc telluride selenide (ZnTeSe), zinc cadmium selenide (ZnCdSe), zinc cadmium sulfide (CdSeS), and/or cadmium zinc sulfide selenide (CdZnSSe). In an embodiment, shell 104 may have a thickness 104t, for example, one or more monolayers. In other embodiments, shell 104 may have a thickness 104t between about 1 nm and about 5 nm. Shell 104 may be utilized to help reduce the lattice mismatch with core 102 and improve the QY of NS 101. Shell 104 may also help to passivate and remove surface trap states, such as dangling bonds, on core 102 to increase QY of NS 101. The presence of surface trap states may provide non-radiative recombination centers and contribute to lowered emission efficiency of NS 101.

In alternate embodiments, NS 101 may include a second shell disposed on shell 104, or more than two shells surrounding core 102, without departing from the spirit and scope of the present invention. In an embodiment, the second shell may be on the order of two monolayers thick and is typically, though not required, also a semiconducting material. Second shell may provide protection to core 102. Second shell material may be zinc sulfide (ZnS), although other materials may be used as well without deviating from the scope or spirit of the invention.

Buffered barrier layer 106 is configured to form a coating on NS 101. In an embodiment, buffered barrier layer 106 is disposed on and in substantial contact with outer surface 104a of shell 104. In embodiments of NS 101 having one or more shells, buffered barrier layer 106 may be disposed on and in substantial contact with the outermost shell of NS 101. In an example embodiment, buffered barrier layer 106 is configured to act as a spacer between NS 101 and one or more NSs in, for example, a solution, a composition, and/or a film having a plurality of NSs, where the plurality of NSs may be similar to NS 101 and/or buffered barrier layer coated NS 100. In such NS solutions, NS compositions, and/or NS films, buffered barrier layer 106 may help to prevent aggregation of NS 101 with adjacent NSs. Aggregation of NS 101 with adjacent NSs may lead to increase in size of NS 101 and consequent reduction or quenching in the optical emission properties of the aggregated NS (not shown) including NS 101. Buffered barrier layer 106 may also prevent NS 101 from reabsorbing optical emissions from other NSs in the NS solutions, NS compositions, and/or NS films and thus, improve the QY of these NS solutions, NS compositions, and/or NS films. In further embodiments, buffered barrier layer 106 provides protection to NS 101 from, for example, moisture, air, and/or harsh environments (e.g., high temperatures and chemicals used during lithographic processing of NSs and/or during manufacturing process of NS based devices) that may adversely affect the structural and optical properties of NS 101. In some embodiments, buffered barrier layer 106 is configured to reduce degradation of NS 101 by light flux, heat, oxygen, moisture, or a combination thereof.

Buffered barrier layer 106 includes one or more materials that are amorphous, optically transparent, and/or electrically conductive and/or non-conductive. In some embodiments, due to conductive buffered barrier layer 106, NSs such as NS 100 may be suitable for NS-based electroluminescence devices (e.g., NS-based LEDs). Suitable buffered barrier layers include inorganic materials, such as, but not limited to, inorganic oxides and/or nitrides. Examples of materials for buffered barrier layer 106 include oxides and/or nitrides of Al, Ba, Ca, Mg, Ni, Si, Ti, Zn, or Zr, according to various embodiments. In some embodiments, buffered barrier layer 106 includes mixed composition of metal and non-metal oxides. Examples for metal oxides include ZnO, TiO₂, In₂O₃, Ga₂O₃, SnO₂, Al₂O₃, MgO, aluminum zinc oxide (AZO), gallium zinc oxide (GZO), indium zinc oxide (IZO), fluorine doped tin oxide (FTO), indium tin oxide (ITO), or a combination thereof. In some embodiments, buffered barrier layer 106 include nanoparticles of inorganic materials, such as, but not limited to, metal oxides (e.g., ZnO, TiO₂, In₂O₃, Ga₂O₃, SnO₂, Al₂O₃, MgO, AZO, GZO, IZO, FTO, ITO). Presence of transparent conductive oxides in buffered barrier layer 106 such as, but not limited to, AZO, GZO, IZO, FTO, ITO may improve the conductive properties of NS 100 and make NS 100 suitable for NS-based electroluminescence devices. Buffered barrier layer 106 may have a thickness 106t ranging from about 8 nm to about 15 nm in various embodiments. In some embodiments, thickness 106t may have a minimum value such that a center-to-center distance between two adjacent NSs 100, for example, in a solution, composition, and/or film is equal to or greater than a Forster radius (also referred in the art as Forster distance) in order to reduce or substantially eliminate resonance energy transfer and/or reabsorption of optical emission between the adjacent NSs 100, and consequently, improve QY of the adjacent NSs 100. In some embodiments, thickness 106t may have a minimum value of between about 8 nm to about 15 nm.

Forster radius refers to a center-to-center distance between two adjacent NSs, such as NSs 100 at which resonance energy transfer efficiency between these two adjacent NSs is about 50%. Having a center-to-center distance between two adjacent NSs greater than the Forster radius may decrease the resonance energy transfer efficiency and improve the optical emission properties and QY of the adjacent NSs. The process of resonance energy transfer can take place when one NS in an electronically excited state transfers its excitation energy to a nearby or adjacent NS. The resonance energy transfer process is a non-radiative quantum mechanical process. Thus, when the resonance energy transfer occurs from the one NS, the optical emission properties of the one NS may be quenched and the QY of the one NS may be adversely affected.

Buffered barrier layer coated NS 100 may additionally or optionally include a buffer layer 107 configured to form a buffered coating on NS 101. In an embodiment, buffer layer 107 is disposed on shell 104 and in substantial contact with outer surface 104a of shell 104 and inner surface 106a of buffered barrier layer 106. In embodiments of NS 101 having one or more shells, buffer layer 107 may be disposed on and in substantial contact with the outermost shell of NS 101. Buffer layer 107 may be configured to act as a buffer between NS 101 and chemicals used during subsequent processing on NS 101, such as, for example, formation of barrier layer 106 on NS 101.

Buffer layer 107 may help to substantially reduce and/or prevent quenching in the optical emission properties of NS 101 due to reaction with chemicals used during subsequent processing on NS 101. The substantial reduction and/or prevention of quenching in the optical emission properties of NS 101 may be due to elimination of surface hole trap sites of NS 101 by buffer layer 107. In some embodiments, the presence of buffer layer 107, nanoparticles of inorganic materials in buffered barrier layer 106 and/or mixed composition of metal and non-metal oxides in buffered barrier layer 106 may improve stability and charge transport properties of NS 101.

Buffer layer 107 may include one or more materials that are amorphous, optically transparent and/or electrically active. The one or more materials of buffer layer 107 may include inorganic or organic materials. Examples of inorganic materials for buffer layer 107 include oxides and/or nitrides of metals, according to various embodiments. Examples for metal oxides include ZnO, TiO₂, In₂O₃, Ga₂O₃, SnO₂, Al₂O₃, or MgO. Buffer layer 107 may have a thickness 107t ranging from about 1 nm to about 5 nm in various embodiments.

As illustrated in FIG. 1, buffered barrier layer coated NS 100 may additionally or optionally include a plurality of ligands or surfactants 108, according to an embodiment. Ligands or surfactants 108 may be adsorbed or bound to an outer surface of buffered barrier layer coated NS 100, such as on an outer surface of buffered barrier layer 106, according to an embodiment. The plurality of ligands or surfactants 108 may include hydrophilic or polar heads 108a and hydrophobic or non-polar tails 108b. The hydrophilic or polar heads 108a may be bound to buffered barrier layer 106. The presence of ligands or surfactants 108 may help to separate NS 100 and/or NS 101 from other NSs in, for example, a solution, a composition, and/or a film during their formation. If the NSs are allowed to aggregate during their formation, the quantum efficiency of NSs such as NS 100 and/or NS 101 may drop. Ligands or surfactants 108 may also be used to impart certain properties to buffered barrier layer coated NS 100, such as hydrophobicity to provide miscibility in non-polar solvents, or to provide reaction sites (e.g., reverse micellar systems) for other compounds to bind.

A wide variety of ligands exist that may be used as ligands 108. In some embodiments, the ligand is a fatty acid selected from lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from dodecylamine, oleylamine, hexadecylamine, and octadecylamine. In some embodiments, the ligand is trioctylphosphine (TOP). In some embodiments, the ligand is oleylamine. In some embodiments, the ligand is diphenylphosphine.

A wide variety of surfactants exist that may be used as surfactants 108. Nonionic surfactants may be used as surfactants 108 in some embodiments. Some examples of nonionic surfactants include polyoxyethylene (5) nonylphenylether (commercial name IGEPAL CO-520), polyoxyethylene (9) nonylphenylether (IGEPAL CO-630), octylphenoxy poly(ethyleneoxy)ethanol (IGEPAL CA-630), polyethylene glycol oleyl ether (Brij 93), polyethylene glycol hexadecyl ether (Brij 52), polyethylene glycol octadecyl ether (Brij S10), polyoxyethylene (10) isooctylcyclohexyl ether (Triton X-100), and polyoxyethylene branched nonylcyclohexyl ether (Triton N-101).

Anionic surfactants may be used as surfactants 108 in some embodiments. Some examples of anionic surfactants include sodium dioctyl sulfosuccinate, sodium stearate, sodium lauryl sulfate, sodium monododecyl phosphate, sodium dodecylbenzenesulfonate, and sodium myristyl sulfate.

In some embodiments, NSs 101 and/or 100 may be synthesized to emit light in one or more various color ranges, such as red, orange, and/or yellow range. In some embodiments, NSs 101 and/or 100 may be synthesized to emit light in the green and/or yellow range. In some embodiments, NSs 101 and/or 100 may be synthesized emit light in the blue, indigo, violet, and/or ultra-violet range. In some embodiments, NSs 101 and/or 100 may be synthesized to have a primary emission peak wavelength between about 605 nm and about 650 nm, between about 510 nm and about 550 nm, or between about 300 nm and about 480 nm.

NSs 101 and/or 100 may be synthesized to display a high QY. In some embodiments, NSs 101 and/or 100 may be synthesized to display a QY between 70% and 95%, between 80% and 95%, or between 85% and 90%.

Thus, according to various embodiments, NSs 100 may be synthesized such that the presence of buffered barrier layer 106 on NSs 101 does not substantially change or quench the optical emission properties of NSs 101.

QY of NSs may be calculated using an organic dye as a reference. For example, rhodamine (Rh) 640 as a reference for red-emitting NSs 101 and/or 100 at the 530 nm excitation wavelength, fluorescein dye as a reference for green-emitting NSs 101 and/or 100 at the 440 nm excitation wavelength, 1,10-diphenylanthracene as a reference for blue-emitting NSs 101 and/or 100 at the 355 nm excitation wavelength. This can be achieved using the following equation:

$${Φ}_{X} = {Φ}_{ST} ( \frac{{Grad}_{X}}{{Grad}_{ST}} ) ( \frac{{η}_{X}^{2}}{{η}_{ST}^{2}} ) .$$

The subscripts ST and X denote the standard (reference dye) and the core/shell NSs solution (test sample), respectively. Φ_{X} is the quantum yield of the core/shell NSs, and Φ_{ST} is the quantum yield of the reference dye. Grad=(I/A), where I is the area under the emission peak (wavelength scale); A is the absorbance at excitation wavelength. η is the refractive index of the reference dye or the core/shell NSs in the solvent. See, e.g., Williams et al. (1983) “Relative fluorescence quantum yields using a computer controlled luminescence spectrometer” Analyst 108:1067. The references listed in Williams et al. are for green and red emitting NSs.

### An Example Method for Forming a Core-Shell NSs

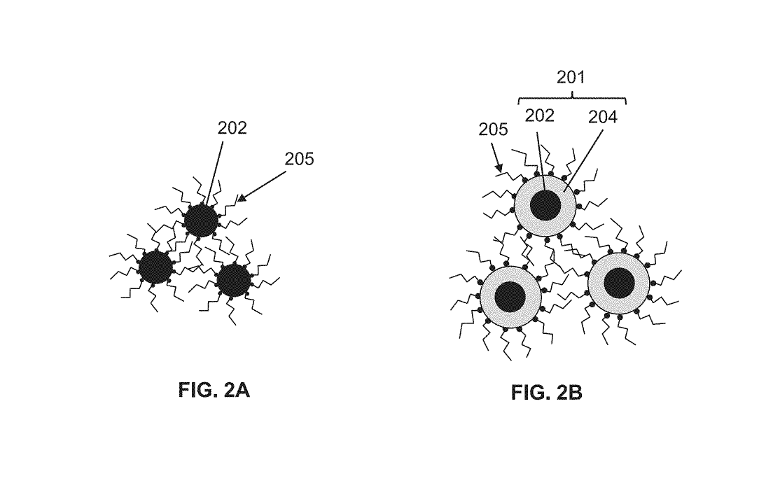

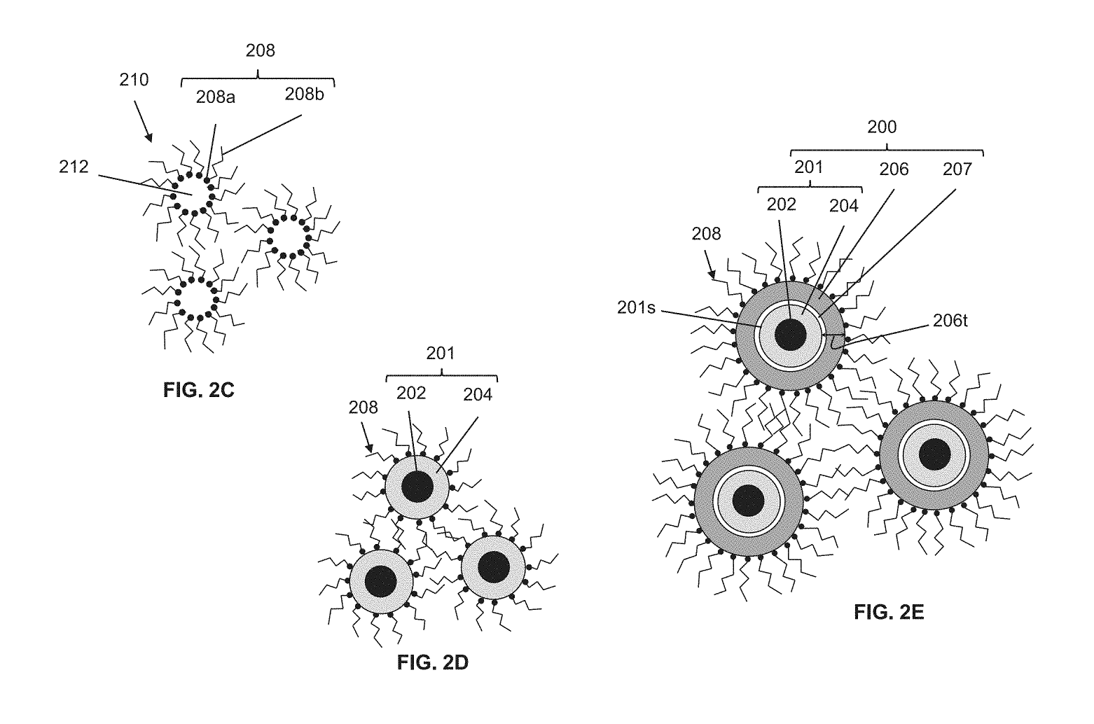

FIGS. 2A-2E illustrate different stages of formation of NSs 200, according to an embodiment. NSs 200 may be similar to NS 100, as described above. It should be noted that formation of three NSs has been shown in FIGS. 2A-2E for illustrative purposes. However, as would be understood by a person of skill in the art based on the description herein, the methods described below can produce any number of NSs similar to NSs 200.

Cores formation—FIG. 2A illustrates NSs 201 after formation of cores 202 and native ligands or surfactants 205, according to an embodiment. Cores 202 and native ligands 205 may be similar to core 102 and ligands 108, respectively. In an embodiment, cores 202 having native ligands or surfactants 205 attached to their outer surface may be formed using a solution-phase colloidal method. The colloidal method may include forming a first mixture comprising one or more cation precursors, one or more anion precursors, and a solvent. The method may further include heating a solution of one or more ligands or surfactants at a first temperature and forming a second mixture by rapidly injecting the first mixture into the heated solution of one or more ligands or surfactants, followed by heating the second mixture at a second temperature. The one or more ligands or surfactants can be any of the ligands or surfactants discussed above. In some embodiments, the first temperature is between about 200° C. and about 400° C. and in some embodiments, the second temperature is between about 150° C. and about 350° C. The first temperature may be selected to be sufficient enough to induce a reaction between the cation precursors and the anion precursors. The cation and anion precursors may react to form nuclei of reaction products. For example, a cation precursor such as a cadmium precursor and an anion precursor such as a selenium precursor may react in the heated mixture to form CdSe nuclei.

After this initial nucleation phase, growth of cores 202 from the nuclei may occur through addition of monomers, which are present in the second mixture, to the nuclei at the second temperature that is lower than the first temperature. The growth of cores 202 may be stopped by removing the heating at the second temperature after a desired size and/or shape is achieved. This heating process at the second temperature may last from about 1 min to about 120 min. The size and/or shape of the resulting cores 202 may be controlled by manipulating, independently or in combination, parameters such as the temperature, types of precursor materials, and ratios of ligands or surfactants to monomers, according to various example embodiments. The size and/or shape of the resulting cores 202 may be determined using techniques known to those of skill in the art. In some embodiments, the size and/or shape is determined by comparing the diameter of cores 202 before and after the addition of monomers. In some embodiments, the diameter of cores 202 before and after the addition of monomers is determined by transmission electron microscopy (TEM).

After the growth of cores 202 to a desired size and/or shape, they can be cooled. In some embodiments, cores 202 are cooled to room temperature. In some embodiments, an organic solvent is added to dilute the second mixture comprising cores 202. In some embodiments, the organic solvent is hexane, pentane, toluene, benzene, diethylether, acetone, ethyl acetate, dichloromethane (methylene chloride), chloroform, dimethylformamide, or N-methylpyrrolidinone. In some embodiments, the organic solvent is toluene.

In some embodiments, after the growth of cores 202 to a desired size and/or shape, they are isolated. In some embodiments, cores 202 are isolated by precipitating them from the solvent of the second mixture or of the diluted second mixture. In some embodiments, cores 202 are isolated by flocculation with methanol, ethanol, isopropanol, or n-butanol.

In an example of this embodiment, the cation precursors may serve as a source for the electropositive element or elements in the resulting cores 202. The cation precursor can be a group II metal (e.g., Zn, Cd, or Hg), a group III metal (e.g., Al, Ga, or In), a group IV (e.g., Ge, Sn or Pb), or a transition metal (e.g., Ti, Zr, Hf, V, Nb, Ta, Cr, Mo, W, Mn, Tc, Re, Fe, Co, Ni, Pd, Pt, Rh, and the like) precursor, according to various example embodiments. The cation precursor can constitute a wide range of substances, such as a metal oxide, a metal carbonate, a metal bicarbonate, a metal sulfate, a metal sulfite, a metal phosphate, metal phosphite, a metal halide, a metal carboxylate, a metal alkoxide, a metal thiolate, a metal amide, a metal imide, a metal alkyl, a metal aryl, a metal coordination complex, a metal solvate, or a metal salt, to provide some examples.

In another example of this embodiment, the anion precursors may serve as a source for the electronegative element or elements in the resulting cores 202. The anion precursor can be selected from the element itself (oxidation state zero), covalent compounds, or ionic compounds of the group V elements (N, P, As, or Sb), the group VI elements (O, S, Se or Te), and the group VII elements (F, Cl, Br, or I), according to various example embodiments.

Examples of the ligands used in the first mixture include dodecylamine (DA), hexadecylamine (HA), octadecylamine (OA), stearic acid (SA), lauric acid (LA), hexylphosphonic acid (HPA), tetradecylphosphonic acid (TDPA), trioctylphosphine (TOP), or trioctylphosphine oxide (TOPO). In an embodiment, the ligand and the solvent may be the same chemical used in the first mixture. For example, long-chain fatty acids and amines and TOPO may serve both the solvent and the ligand functions.

Shelling process—The core formation process may be followed by a shelling process of NSs 201. FIG. 2B illustrates NSs 201 after formation of shells 204. Shells 204 may be similar to shell 104, as described above. The process of forming shells 204 around cores 202 may include suspending cores 202 in a solvent or a mixture of solvents such as, but not limited to, 1-octadecene, 1-decene, 1-dodecene, or tetradecane, and heating the suspension of cores 202 at a third temperature. In some embodiments, the third temperature is between 100° C. and about 200° C. The shelling process may further include forming a third mixture by adding precursors that include elements of shells 204 at a fourth temperature. In some embodiments, the fourth temperature is between 250° C. and about 350° C. For example, cadmium precursor and sulfur precursor may be used in the third mixture for forming shells 204 comprising cadmium sulfide (CdS). In an example, shells 204 include group III-V material or group II-VI material. In another example, elements of shells 204 may be different from elements of cores 202. The materials of cores 202 and shells 204 may be selected such that the two materials have a low lattice mismatch between them. The low lattice mismatch may allow the formation of a uniform and epitaxially grown shells 204 on the surfaces of cores 202. In this method of first shell formation, cores 202 may act as the nuclei, for shells 204 to grow from their surface.

The growth of shells 204 on cores 202 may be stopped by removing the heating at the fourth temperature after a desired thickness of shells 204 on cores 202 is achieved. This heating process at the fourth temperature may last from about 50 min to about 100 min. The thickness of the resulting shells 204 may be controlled by manipulating, independently or in combination, parameters such as the temperature, types of precursor materials, and amount of precursors, according to various example embodiments.

After the growth of shells 204 to a desired thickness, the resulting core-shell NSs 201 can be cooled. In some embodiments, NSs 201 are cooled to room temperature. In some embodiments, after the formation of NSs 201, they are isolated. In some embodiments, NSs 201 are isolated by precipitation with a solvent (e.g., ethanol) and centrifugation.

In alternate embodiments, the above NS 201 formation method may include doping cores 202 during synthesis of cores 202. The doping process may be performed at any stage of NS 201 formation. For example, one or more dopant precursors may be introduced with the cation precursor or the anion precursor during cores 202 synthesis process or with the precursors during the shelling process.

The cores 202 may have one or more dopants homogeneously or heterogeneously distributed throughout the cores 202. For example, higher dopant concentration may be present at the surface of the cores 202 and lower dopant concentration may be present at the center of the cores, or vice versa. In another example, the one or more dopants may be distributed substantially uniformly over the cores 202.

According to an example of this embodiment, the one or more dopant precursors may include any suitable doping precursors such as, but not limited to, metal oxide (e.g., zinc oxide, magnesium oxide), metal acetate (e.g., zinc acetate, cobalt acetate), metal carbonate (e.g., zinc carbonate, cobalt carbonate, magnesium carbonate), metal bicarbonate (e.g., zinc bicarbonate, cobalt bicarbonate, magnesium bicarbonate), metal sulfate (e.g., zinc sulfate, magnesium sulfate, cobalt sulfate), metal sulfite (e.g., zinc sulfite, magnesium sulfite), metal phosphate (e.g., zinc phosphate, cobalt phosphate, magnesium phosphate), metal phosphite (e.g., zinc phosphite, magnesium phosphite), metal halide (e.g., zinc halide, magnesium halide), metal carboxylate (e.g., zinc carboxylate, magnesium carboxylate), metal alkoxide (e.g., zinc alkoxide, magnesium alkoxide), metal thiolate (e.g., zinc thiolate, magnesium thiolate), metal amide (e.g., zinc amide, magnesium amide), metal imide (e.g., zinc imide, magnesium imide), metal alkyl (e.g., zinc alkyl, aluminum alkyl, magnesium alkyl), or diethyl metal (e.g., diethyl zinc).

The resulting core-shell NSs 201 may have a narrow size distribution (i.e., a small FWHM) and a high QY. In some embodiments, the photoluminescence spectrum of core-shell NSs 201 have a FWHM in a range from about 20 nm and 50 nm, from about 22 nm and 50 nm from about 24 nm and 50 nm, from about 26 nm and 50 nm, from about 28 nm and 50 nm, from about 20 nm and 46 nm, from about 20 nm and 42 nm, from about 20 nm and 36 nm, from about 20 nm and 34 nm, or from about 20 nm and 30 nm.

In some embodiments, core-shell NSs 201 may be synthesized to emit light in one or more various color ranges, such as red, orange, and/or yellow range. In some embodiments, core-shell NSs 201 may be synthesized to emit light in the green and/or yellow range. In some embodiments, core-shell NSs 201 may be synthesized to emit light in the blue, indigo, violet, and/or ultra-violet range. In some embodiments, core-shell NSs 201 may be synthesized to have a primary emission peak wavelength between about 605 nm and about 650 nm, between about 510 nm and about 550 nm, or between about 300 nm and about 480 nm.

In some embodiments, core-shell NSs 201 may be synthesized to display a high QY. In some embodiments, core-shell NSs 201 may be synthesized to display a QY between 60% and 95%, between 70% and 95%, between 80% and 95%, or between 85% and 90%.

The formation of core-shell NSs 201 may be followed by formation of buffered barrier layer coated NSs 200, as illustrated in FIGS. 2C-2E. In an embodiment, NSs 200 may be similar to NSs 100 described above. In an embodiment, the method of forming buffered barrier layer coated NSs 200 is based on a reverse emulsion method that includes formation of reverse micro-micelles 210. These reverse micro-micelles 210 may serve as reaction centers for buffered coating of core-shell NSs 201 with buffered barrier layer 206. In an embodiment, formation of NSs 200 may involve formation of reverse micro-micelles 210, incorporation of core-shell NSs 201 into reverse micro-micelles 210, a buffered barrier layer coating process of the incorporated core-shell NSs 201, as described below. In some embodiments, formation of NSs 200 may additionally or optionally include an acid etch treatment performed after the buffered barrier layer coating process, that is after the formation of buffered barrier layer 206. NSs 201 having a core 202 and one or more shells 204 may be similar to core-shell NSs 101 described above. Cores 202 may be similar to core 101 and one or more shells 204 may be similar to shell 104 described above.

Reverse micro-micelles formation—FIG. 2C illustrates reverse micro-micelles 210 formed in a reverse emulsion (not shown), according to an embodiment. Formation of reverse micro-micelles 210 may include forming a reverse emulsion and adding surfactants 208 in the reverse emulsion. The emulsion may be formed by mixing two immiscible liquids such as a hydrophilic polar solvent and a hydrophobic non-polar solvent, according to an embodiment. Water may be used as a polar solvent and a hydrocarbon may be used as a hydrophobic non-polar solvent. Examples of hydrocarbon that can be used as a hydrophobic non-polar solvent include cyclopentane, cyclohexane, cycloheptane, toluene, or hexane. The two immiscible liquids in the reverse emulsion tend to separate into two distinct phases, a continuous phase and a non-continuous phase, due to their immiscibility with each other. In some embodiments, the two distinct phase are a continuous non-aqueous phase (e.g., hydrocarbon phase) and a non-continuous aqueous phase.

In some embodiments, the two distinct phases in the reverse emulsion may be stabilized by the addition of surfactants 208 to form a first mixture. Surfactants 208 may be similar to surfactants 108. Some examples of surfactants 208 include polyoxyethylene (5) nonylphenylether (commercial name IGEPAL CO-520), polyoxyethylene (9) nonylphenylether (IGEPAL CO-630), octylphenoxy poly(ethyleneoxy)ethanol (IGEPAL CA-630), polyethylene glycol oleyl ether (Brij 93), polyethylene glycol hexadecyl ether (Brij 52), polyethylene glycol octadecyl ether (Brij S10), polyoxyethylene (10) isooctylcyclohexyl ether (Triton X-100), polyoxyethylene branched nonylcyclohexyl ether (Triton N-101), sodiumdioctyl sulfosuccinate, sodium stearate, sodium lauryl sulfate, sodium monododecyl phosphate, sodium dodecylbenzenesulfonate, and sodium myristyl sulfate.

Surfactants 208 may help to stabilize the non-continuous aqueous phase by forming a dispersion of reverse micro-micelles 210 in the reverse emulsion to isolate the non-continuous aqueous phase into regimes of aqueous phases within cores 212 of reverse micro-micelles 210. Each of the reverse micro-micelles 210 may be formed by a group of surfactants from among surfactants 208 added into the reverse emulsion. In some embodiments, each of the reverse micro-micelles 210 includes a hydrophilic portion formed by hydrophilic polar groups 208a (sometimes referred to as heads in the art) of surfactants 208 and a hydrophobic portion formed by hydrophobic non-polar groups 208b (sometimes referred to as tails in the art) of surfactants 208. In each of reverse micro-micelles 210, hydrophilic polar heads 208a soluble in the aqueous phase may form a hydrophilic shell around the aqueous phase contained within each of reverse micro-micelle cores 212 and corresponding hydrophobic non-polar tails 208b soluble in the continuous non-aqueous phase may form a hydrophobic shell surrounding the hydrophilic shell. In some embodiments, reverse micelles 210 have a spherical shape and the size of reverse micelles 210 can be controlled by manipulating the type and/or amount of surfactants 208 added in the reverse emulsion.

Incorporation of core-shell NSs into reverse micro-micelles—The formation of reverse micro-micelles 210 may be followed by incorporation of core-shell NSs 201 into cores 212 of reverse micro-micelles 210, as illustrated in FIG. 2D. In an embodiment, this incorporation process includes forming a NS solution having core-shell NSs 201 dispersed in a solvent (e.g., cyclohexane, toluene, or hexane). The incorporation process further includes forming a second mixture of the NS solution and the first mixture having reverse micro-micelles 210, according to an embodiment.

Similar to NSs 101, NSs 201 may have native ligands or surfactants (not shown) bonded on the outer surface of the outermost shell 204 before adding to the reverse emulsion. These native ligands or surfactants of NSs 201 may have similar affiliation to NSs 201 as the hydrophilic polar heads 208a of surfactants 208. The native ligands or surfactants (not shown here) may be dynamically bonded to NSs 201, i.e. the native ligands or surfactants may be bonded to NSs 201 in an on-and-off fashion, which may provide the opportunity for the native ligands or surfactants to be substituted by surfactants 208 in the reverse emulsion. In some embodiments, these native ligands or surfactants of NSs 201 have hydrophilic groups, which causes NSs 201 in the second mixture to be drawn to the aqueous phases isolated within cores 212 of reverse micro-micelles 510 and be enclosed within cores 212, as illustrated in FIG. 2D. Each of these NS-filled reverse micro-micelles 210 in the second mixture provides an environment or a reaction center for the formation of buffered barrier layer 206 and an optional buffer layer 207 on each of the NSs 201 enclosed within the reverse micro-micelles 210. Buffered barrier layer 206 and buffer layer 207 may be similar to buffered barrier layer 106 and buffer layer 107, respectively, according to an embodiment.

In some embodiments, each of the reverse micro-micelles 210 encloses one of the NSs 201 in the second mixture. Such one-in-one incorporation of NSs 201 into reverse micro-micelles 210 may help to prevent aggregation of the NSs 201 with each other and allow individual buffered coating of the NSs 201. In some embodiments, during the formation of buffered barrier layer 206, substantially all the native ligands or surfactants of NSs 201 may be exchanged or replaced by the surfactants of the reverse micro-micelles. In some embodiments, after one or more of the NSs 201 are individually enclosed by a buffered barrier layer 206, there may be no native ligands or surfactants left between NSs 201 and the buffered barrier layer 206. Instead, the native ligands or surfactants may be driven out of the interface between NSs 201 and buffered barrier layer 206 into the continuous hydrophobic phase. The native ligands or surfactants in the continuous hydrophobic phase may be bonded to the surface of the buffered barrier layer 206. It should be noted that even though FIG. 2C-2E illustrates an equal number of NSs 201 and reverse micro-micelles 210, a person skilled in the art would understand based on the description herein that in some embodiments the number of reverse micro-micelles, similar to reverse micro-micelles 210, formed in the reverse emulsion may be greater than the number of core-shell NSs, similar to core-shell NSs 201, added to the reverse emulsion. In such embodiments, some of the reverse micelles may remain empty of core-shell NSs.

Addition of buffer agent into reverse micro-micelles—According to an embodiment, following the incorporation of NSs 201 into the reverse micro-micelles 210 in the second mixture, a third mixture is prepared by adding an organic or inorganic buffer agent into the second mixture. For example, organic buffer agent, such as TOP, diphenylphosphine, tributylphosphine, or other aliphatic phosphines, or inorganic buffer agent such as metal salts may be added to the second mixture. Examples for metal salt buffer agent include zinc oleate, ZnCl₂, ZnEt₂, or Zn(OAc)₂, aluminum chloride, aluminum iodide, aluminum bromide, aluminum acetate, aluminum oleate, indium chloride, indium acetate, magnesium chloride, magnesium oleate, et al.

In some embodiments, organic buffer agents may form a temporary organic buffer layer (not shown) on or around each of the NSs 201 within the reverse micro-micelles 210 to shield the NSs 201 from direct attack by chemicals used in subsequent processing, such as catalysts NH₄OH used in subsequent buffered barrier layer 206 formation on NSs 201 (shown in FIG. 2E). Although organic buffer agent may leave the surface of the NSs 201 and enter into the continuous hydrophobic phase when a monolayer of buffered barrier layer 206 is formed, the temporary presence of organic buffer layer on the NSs 201 may help to substantially reduce and/or prevent the degree of quenching in the optical emission properties of the NSs 201 during the subsequent processing.

In some embodiments, inorganic buffer agents may react with chemicals used in subsequent processing, such as catalysts NH₄OH used in subsequent buffered barrier layer 206 formation to form an inorganic buffer layer such as buffer layer 207 (shown in FIG. 2E) on or around each of the NSs 201 within the reverse micro-micelles 210. Inorganic buffer layer 207 may shield the NSs 201 from direct attack by chemicals used in subsequent processing of NSs 201. Buffer layer 207 may be similar to buffer layer 107 described above. Additionally or optionally, inorganic buffer agents may react with the chemicals to form inorganic molecules or inorganic nanoparticles incorporated in buffered barrier layer 206. The presence of buffer layer 207, inorganic molecules, and/or inorganic nanoparticles may help to substantially reduce and/or prevent the degree of quenching in the optical emission properties of the NSs 201 during the subsequent processing.

Buffered Barrier Layer formation—According to an embodiment, following the incorporation of NSs 201 into the reverse micro-micelles 210 in the second mixture and addition of buffer agent into the second mixture, barrier layer 206 is formed on each of the incorporated NSs 201, as illustrated in FIG. 2E. In an embodiment, the formation of buffered barrier layer 206 includes forming a fourth mixture of the third mixture and one or more precursors that have elements of buffered barrier layer 206. For example, Al, Ba, Ca, Mg, Ni, Si, Ti, or Zr precursor may be added to the third mixture for forming buffered barrier layer 206 comprising oxides and/or nitrides of Al, Ba, Ca, Mg, Ni, Si, Ti, or Zr. In some embodiments, tetraethyl orthosilicate (TEOS), tetramethyl orthosilicate, tetrapropyl orthosilicate, or tetrabutyl orthosilicate is used as a Si precursor. The one or more precursors may be prepared as a solution and added into the third mixture at a rate between about 6 mL/min and 8 mL/min, while the second mixture may be rigorously stirred.

The formation of buffered barrier layer 206 further includes forming a fifth mixture of one or more catalysts and the fourth mixture, according to an embodiment. In an embodiment, ammonium hydroxide is added as a catalyst to the fifth mixture. The one or more catalysts may be prepared as a solution and added into the fourth mixture at a rate between about 4 mL/min and 7 mL/min, while the fifth mixture may be rigorously stirred. Both the added precursors and catalysts are drawn to NSs 201 in the aqueous phase of reverse micelles 210 due to their affiliation with the hydroxyl (OH) group. Once the added precursor and catalysts are enclosed with a corresponding one of the NSs 201 within each of the reverse micelles 210, the one or more catalysts may react with the buffer agent(s) as described above and the added one or more precursors may undergo catalyzed hydrolysis to transform into an intermediate form (hydrolyzed silicon precursor). In some embodiments, surfactants 208 bonded to NSs 201 are completely substituted by hydrolyzed silicon precursors to form a monolayer of hydrolyzed silicon precursors, which further undergo condensation to form an individual coating of buffered barrier layer 206 around the corresponding one of the NSs 201. For example, once a Si precursor such as TEOS and ammonium hydroxide catalyst are drawn into and enclosed with a corresponding one of the NSs 201 within reaction center provided by each of the reverse micro-micelles 210, TEOS undergoes ammonium hydroxide catalyzed hydrolysis to transform into an intermediate form, tetrahydroxysilane, which further undergoes condensation to form an individual coating of buffered SiO₂ barrier layer 206 around the corresponding one of the NSs 201. In some embodiments, this hydrolysis and condensation of the one or more precursors added is performed without stirring and/or heating the fifth mixture. In some embodiments, this hydrolysis and condensation reaction may be allowed to occur from about 1 day to about 7 days until substantially all of the one or more precursors in the fifth mixture are used up.

The thickness of the buffered barrier layer 206 formed may be controlled by manipulating, independently or in combination, parameters such as the amount of precursor, the concentration of NSs, and the hydrolysis and condensation reaction time. In an embodiment, increasing the concentration or number of NSs 201 in the second mixture for the same amount of precursors in the fourth mixture may reduce the thickness of the buffered barrier layer 206. In another embodiment, the thickness of the buffered barrier layer 206 may be controlled by terminating the hydrolysis and condensation reactions by deactivating the catalyst (e.g., neutralizing the ammonium hydroxide with an acid, or evaporating the ammonia by vacuum).

In alternate embodiments, the amount of the one or more precursors that may be needed to achieve the desired thickness of buffered barrier layer 206 is added in two or more stages of the barrier layer growth process. For example, a portion of the precursor amount may be added to the third mixture to make the fourth mixture and the remaining portion of the precursor amount may be added to the fifth mixture after the precursors of the fourth mixture has been used up during the hydrolysis and condensation reaction.

Buffered barrier layer 206 may be grown to a thickness 206t ranging from about 8 nm to about 15 nm in various embodiments. In some embodiments, thickness 206t may have a minimum value such that a center-to-center distance between two adjacent NSs 200, for example, in a solution, composition, and/or film is equal to or greater than a Forster radius. In some embodiments, thickness 206t may have a minimum value of between about 8 nm to about 15 nm.

Acid Etch Treatment—After the growth of buffered barrier layers 206 to a desired thickness, an acid etch treatment may be performed on NSs 200, according to an embodiment. In some embodiments, one or more acids may be added to the fifth mixture to form a sixth mixture. Examples of the one or more acids include acetic acid, hydrochloric acid, nitric acid, a fatty acid, or a combination thereof. In some embodiments, the molar ratio in a range from about 1.5 to about 10 may be maintained between the one or more acids and the one or more catalysts in the sixth mixture. In one embodiment, the molar ratio of about 2 may be maintained between acetic acid and ammonium hydroxide catalyst in the sixth mixture. The etching process in the sixth mixture may be performed for a time period ranging from about 5 minutes to about 2 days. The acid etch rate may be varied by varying the concentration of the one or more acids added to the fifth mixture, etching temperature, molar ratio between the one or more acids to the one or more catalysts, and/or thickness of buffered barrier layer 206.

This post-coating acid etch treatment of NSs 200 may help to substantially reduce quenching in the optical emission properties of NSs 201. Such optical quenching may be due to reaction of NSs 201 with chemicals used during processing (e.g., catalyst used during buffered barrier layer coating process) on NS 201 prior to the etching process. For example, the use of ammonium hydroxide catalyst may create coordinating sites on surfaces 201s of NSs 201 for OFF and NH₄⁺ ions. These ions may serve as photoelectron trap sites on surfaces 201s, and the photoelectron trap sites may induce quenching in the optical emission properties of NSs 201. The etching of surfaces 201s during the acid etch treatment may help to etch off such photoelectron trap sites and/or other trap sites and/or defects on surfaces 201s of NSs 201 that induce optical quenching of NSs 201, and consequently, substantially reduce quenching in the optical emission properties of NSs 201. The acid etch treatment of buffered barrier layer coated NSs 200 may be continued until QY of NSs 200 is substantially similar to QY of uncoated NSs 201. That is the acid etch treatment may be continued until negative effects of processing on NSs 201 (e.g., negative effects of buffered barrier layer coating process) are substantially reduced.

It should be noted that even though buffered barrier layers 206 may be present on NSs 201, acid molecules or H⁺ ions from the one or more acids in the sixth mixture can penetrate through buffered barrier layers 206, which are porous, and arrive at surfaces 201s. Also, should be noted that the substantial reduction in optical quenching of NSs 201 due to acid etch treatment may be in addition to that reduced by the use of buffer agent and/or the formation of buffer layer 207, as discussed above.

In some embodiments, the acid etch treatment may be performed on NSs 201 prior to and post the buffered barrier layers 206 formation process.

In some embodiments, the one or more catalysts (e.g., ammonium hydroxide) may be selectively removed, for example by evaporating before adding the one or more acids (e.g., acetic acid) to the fifth mixture to form the sixth mixture for the acid etch treatment of NSs 200.

The acid etch treatment may be followed by removal of the solvent, the unreacted one or more precursors, the one or more catalysts, and reaction byproducts from the sixth mixture. In some embodiments, the solvent, unreacted precursors, and reaction byproducts may be removed by evaporation at a temperature between about 40° C. and about 60° C. under vacuum. The resulting concentrate after removal of the solvent and precursors may be further dried at a temperature between about 50° C. and about 70° C. under vacuum for about 60 min to about 90 min. In some embodiments, the resulting buffered barrier layer coated core-shell NSs 200 may be isolated after the acid etch treatment by precipitation with a solvent (e.g., ethanol) and centrifugation and re-dispersed in a hydrophobic solvent such as but not limited to toluene.

The removal of the solvent, the unreacted one or more precursors, the one or more catalysts, and reaction byproducts by vacuum evaporation may ensure that surfactants 208 remain bonded to the outer surface of NSs 200 as illustrated in FIG. 2E. The hydrophobic tails 208b of surfactants 208 on buffered barrier layer 206 provide a hydrophobic shell that ensures the dispersability of the resulting dried and isolated NSs 200 in hydrophobic environments (e.g., toluene, photoresist materials) for compatibility with, for example, device fabrication processes without adversely affecting the optical properties of the NSs 200.

In contrast to the above described post-synthesis process of NSs 200, current post-synthesis process of NSs typically includes washing the synthesized NSs in hydrophilic solvents such as ethanol, methanol, or water to separate the synthesized NSs from the reaction solution. The washing is then followed by re-dispersing of the washed NSs in hydrophilic alcohols such as ethanol or methanol. The re-dispersed NSs are then subjected to a ligand exchange process at high temperatures (e.g., about 200° C.) to introduce a new surfactant on the re-dispersed NSs. The introduction of the new surfactant is to provide a hydrophobic shell on the NSs, as the surfactants that may be present on the synthesized NSs are removed during the washing. The exposure to water or hydrophilic solvents in current post-synthesis process of NSs quenches the optical emission properties of the washed NSs as water creates non-radiative centers that adversely affects the emission properties of the washed NSs. The high temperature ligand exchange process also has a negative effect on the optical emission properties of the NSs.

The isolated and re-dispersed NSs 200 may have a narrow size distribution (i.e., a small FWHM) and a high QY similar to NSs 201. In some embodiments, the photoluminescence spectrum of both NSs 201 and 200 have a FWHM in a range from about 20 nm and 50 nm, from about 22 nm and 50 nm from about 24 nm and 50 nm, from about 26 nm and 50 nm, from about 28 nm and 50 nm, from about 20 nm and 46 nm, from about 20 nm and 42 nm, from about 20 nm and 36 nm, from about 20 nm and 34 nm, or from about 20 nm and 30 nm.

In some embodiments, both NSs 200 and 201 may emit light in one or more various color ranges, such as red, orange, and/or yellow range. In some embodiments, both NSs 200 and 201 emit light in the green and/or yellow range. In some embodiments, both NSs 200 and 201 may emit light in the blue, indigo, violet, and/or ultra-violet range. In some embodiments, both NSs 200 and 201 may have a primary emission peak wavelength between 605 nm and 650 nm, between 510 nm and 550 nm, or between 300 nm and 480 nm.

In some embodiments, both NSs 200 and 201 display a high QY. In some embodiments, Cd-based NSs such as NSs 200 and 201 display a QY between 80% and 95% or between 85% and 90%. Thus, according to various embodiments, the presence of buffered barrier layer 206 on NSs 201 does not substantially change or quench the optical emission properties of NSs 201.

In some embodiments, buffered barrier layer coated NSs 200 display a higher QY than barrier layer coated NSs prepared without buffering. In some embodiments, buffered barrier layer coated NSs 200 display a QY that is about 2 to 6 times higher than QY displayed by barrier layer coated NSs without buffering. In some embodiments, buffered barrier layer coated NSs 200 subjected to acid etch treatment display a QY that is about 10% to about 20% higher than QY displayed by buffered barrier layer coated NSs without acid etch treatment.

It should be noted that three reverse micro-micelles 210, three core shell NSs 201, and three barrier layer coated core-shell NSs 200 have been shown in FIGS. 2C-2D, respectively, for illustrative purposes. However, as would be understood by a person of skill in the art based on the description herein, the methods described above can produce any number of reverse micro-micelles, core shell NSs, and barrier layer coated core-shell NSs similar to reverse micro-micelles 210, core shell NSs 201, and barrier layer coated core-shell NSs 200, respectively.

### An Example Method for Forming Buffered SiO₂ Coated InP/ZnSe/ZnS Core-Shell NSs

The following example method demonstrates growth of highly luminescent buffered SiO₂ coated red-emitting InP/ZnSe/ZnS NSs. According to some embodiments, with minimal variation, the method described below can be used to synthesize buffered SiO₂ coated green-emitting InP/ZnSe/ZnS NSs.

The SiO₂ coated NSs may be similar to NSs 100 and/or 200, according to an embodiment. The buffered SiO₂ coated InP/ZnSe/ZnS NSs have a core/shell structure that may be similar to NSs 101 and/or 201 and also have a buffered SiO₂ barrier layer that may be similar to buffered barrier layer 106 and/or 206 described above. It is understood that the following example method is for illustrative purposes only and is not intended to limit the scope of the present invention. Also, it is understood that the following example method can be performed within a wide and equivalent range of conditions, formulations and other parameters without affecting the scope of the invention or any embodiment thereof.

InP/ZnSe/ZnS core-shell NSs formation—A solvent was prepared by mixing about 6.0 mL 1-octadecene (ODE) and about 3.0 mL trioctylphosphine (TOP) in a 100 mL three neck flask at room temperature and then the reaction was set to about 310° C. Once the temperature was stabilized at about 310° C., a first and second stock solutions were injected simultaneously into the 100 mL three neck flask within about 15 min to about 30 min through syringe pumps. The first and second stock solutions were prepared separately. The first stock solution was prepared as a blend of about 2.0 mL ODE, about 1.8 mL 2.0 M TOP-Se, and 3 mL of an InP core solution in TOP containing about 3600 nmol of InP cores. The first excitonic absorption peak of the InP cores is about 580 nm and the average diameter of the cores is about 2.7 nm. The second stock solution was a 8.9 mL 0.5 M stock solution of zinc(II) oleate in TOP. The first and second stock solutions were used for the formation of first shell ZnSe around InP cores. After the injection of the first and second stock solutions, the reaction was held at about 310° C. for about 5 min to about 15 min.

After holding reaction for about 5 min to about 15 min, a third and fourth stock solutions were injected within about 30 min to about 60 min through syringe pumps for the formation of second shell ZnS around the first shell ZnSe. The third and fourth stock solutions were prepared separately. The third stock solution was about 17.5 mL 0.5 M stock solution of Zn(II) oleate in TOP and the fourth stock solution was prepared as a blend of about 16.8 mL of 1.0 M TOP-sulfur solution, about 4.0 mL TOP, and about 9.5 mL ODE.

After the injection of the third and fourth stock solutions, the reaction solution was held at about 310° C. for about 5 min to about 15 min and then air-cooled to room temperature before being transferred into a glove box for purification. The reaction solution was then diluted with an equal volume of toluene and mixed with an equal volume of ethanol to precipitate the resulting InP/ZnSe/ZnS NSs. The resulting InP/ZnSe/ZnS NSs were isolated from the reaction solution by centrifugation, followed by decantation of the supernatant, and drying under vacuum. The dried InP/ZnS/Se NSs were then re-suspended in cyclohexane to form a solution with a concentration ranging from about 50 nmol/mL to about 100 nmol/mL for measurements such as QY measurements.

The concentration of the resulting InP/ZnSe/ZnS core-shell NSs (in nmol/mL or particle/mL) was determined by dividing the nmol or particle number value of the InP cores used in the synthesis by the volume of the resulting InP/ZnSe/ZnS core-shell NSs-cyclohexane solution. The resulting InP/ZnSe/ZnS core-shell NSs has a narrow size distribution (i.e., a small FWHM) and a high QY.

In some embodiments, the photoluminescence spectrum of the resulting InP/ZnSe/ZnS core-shell NS population has a FWHM in a range from about 20 nm and 50 nm, from about 22 nm and 50 nm from about 24 nm and 50 nm, from about 26 nm and 50 nm, from about 28 nm and 50 nm, from about 20 nm and 46 nm, from about 20 nm and 42 nm, from about 20 nm and 36 nm, from about 20 nm and 34 nm, or from about 20 nm and 30 nm.

In some embodiments, the size of the resulting InP/ZnSe/ZnS core-shell NSs is in a range from about 7.0 nm to about 13.0 nm in diameter, from about 7.2 nm to about 13.0 nm in diameter, from about 7.4 nm to about 13.0 nm in diameter, from about 7.6 nm to about 13.0 nm in diameter, from about 7.8 nm to about 13.0 nm in diameter, from about 8.0 nm to about 13.0 nm in diameter, from about 8.5 nm to about 13.0 nm in diameter, from about 9.0 nm to about 13.0 nm in diameter, from about 10.0 nm to about 13.0 nm in diameter, from about 7.0 nm to about 12.0 nm in diameter, from about 7.0 nm to about 11.0 nm in diameter, from about 7.0 nm to about 10.0 nm in diameter, from about 7.0 nm to about 8.8 nm in diameter, from about 7.2 nm to about 8.6 nm in diameter, from about 7.4 nm to about 8.4 nm in diameter, from about 7.6 nm to about 8.2 nm in diameter, or from about 7.8 nm to about 8.0 nm in diameter.

In some embodiments, the resulting InP/ZnSe/ZnS core-shell NSs emit light in the red, orange, and/or yellow range. In some embodiments, the resulting InP/ZnSe/ZnS core-shell NSs have a primary emission peak wavelength between about 605 nm and about 650 nm. In some embodiments, the InP/ZnSe/ZnS core-shell NSs display a QY between 50% and 80%, between 55% and 75%, between 50% and 70%, or between 55% and 65%.

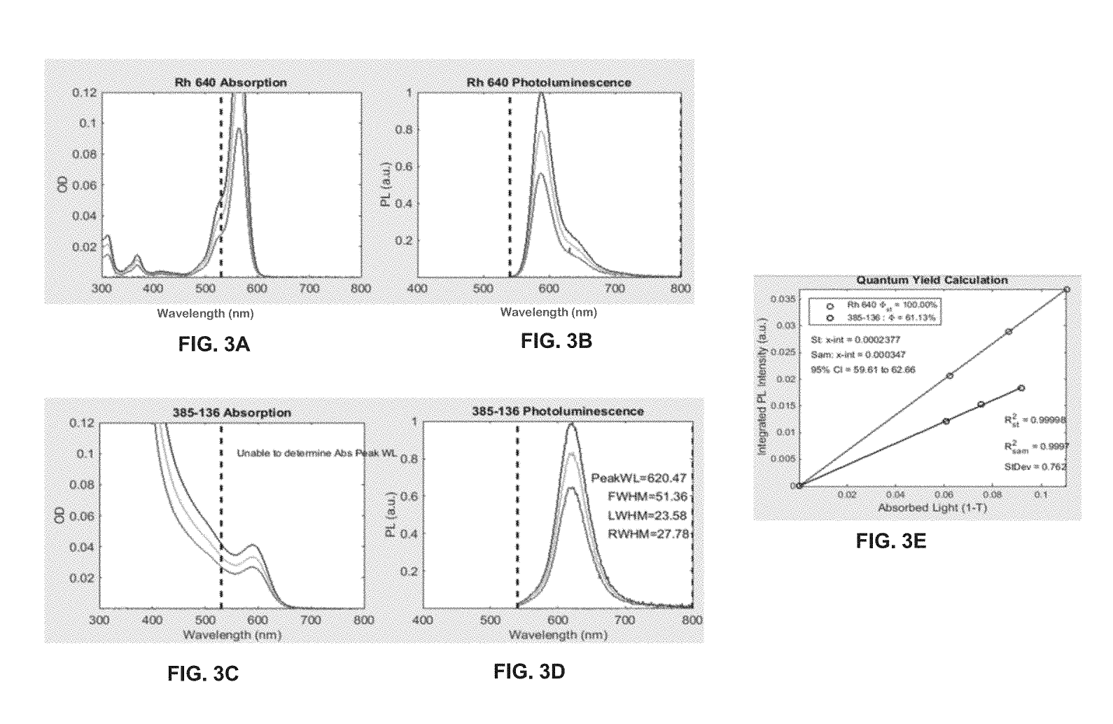

FIGS. 3A-3B show plots of absorption and photoluminescence spectra of different concentrations of the reference dye (rhodamine 640, abbreviated as Rh 640) with an excitation wavelength of 530 nm, respectively, for QY calculation of InP/ZnSe/ZnS core-shell NSs produced by the example methods described above. FIGS. 3C-3D show plots of example absorption and photoluminescence spectra of different concentrations of the InP/ZnSe/ZnS core-shell NSs. FIG. 3E shows QY measurement of the InP/ZnSe/ZnS core-shell NSs obtained based on FIGS. 3A-3D. In an embodiment, the QY measurement of the InP/ZnSe/ZnS core-shell NSs for emission in the red region of the visible spectrum is about 61%.

As described above, the dried InP/ZnS/Se NSs were re-suspended in cyclohexane to form a solution with a concentration ranging from about 50 nmol/mL to about 100 nmol/mL. The InP/ZnS/Se NSs were used in subsequent buffered SiO₂ barrier layer coating of the InP/ZnSe/ZnS NSs.

Reverse micro-micelles formation—A first mixture of stabilized reverse emulsion having reverse micro-micelles was prepared by mixing about 5 mL IGEPAL CO-520, a surfactant, with about 40 mL cyclohexane in a 100 mL bottle. The first mixture was stirred for about 20 min.

Incorporation of InP/ZnS/Se NSs into reverse micro-micelles—After the about 20 min stirring of the first mixture, a second mixture was prepared by adding the InP/ZnS/Se NS solution to the first mixture. The second mixture was stirred for about 20 min after the addition of the InP/ZnS/Se NS solution.

Addition of buffer agent into reverse micro-micelles—After about 20 min stirring of the second mixture, a third mixture was prepared by adding about 3 mL TOP as the organic buffer agent or about 3 mL 0.1 M zinc oleate in TOP as the inorganic buffer agent to the second mixture. The third mixture was stirred for about 20 min after the addition of the buffer agent.

Buffered Barrier Layer formation—Following the about 20 min stirring of the third mixture, a fourth mixture was prepared by adding about 0.3 mL of TEOS, a Si precursor, to the third mixture at a rate of about 1.0 mL/min, while the third mixture was rigorously stirred. The fourth mixture was stirred for about 20 min after the addition of TEOS and was followed by preparation of a fifth mixture. The fifth mixture was prepared by adding about 0.6 mL 30% ammonium hydroxide solution, a catalyst, to the fourth mixture at a rate of about 0.2 mL/min to about 0.3 mL/min, while the fourth mixture was rigorously stirred. The fifth mixture was stirred for about 2 min after the addition of the catalyst. Following the about 2 min stirring, the bottle including the fifth mixture was capped and stored for about 1 to about 7 days without stirring or heating the fifth mixture.

Acid Etch Treatment—After the about 1 to about 7 days of buffered barrier layer coating process, an acid etch treatment was performed on the buffered SiO₂ coated InP/ZnS/Se NSs formed in the fifth mixture, according to an embodiment. Acetic acid was added to the fifth mixture to form a sixth mixture and a molar ratio of about 2 was maintained between the acetic acid and the ammonium hydroxide catalyst.

After about 12 hours of the acid etch treatment of the buffered SiO₂ coated InP/ZnS/Se NSs in the sixth mixture, the solvent, the unreacted TEOS, the ammonium hydroxide, and reaction byproducts such as ethanol were evaporated at or below a temperature of about 50° C. under vacuum to yield acid etch treated buffered SiO₂ coated InP/ZnS/Se NSs having surfactant IGEPAL CO-520 on their outer surfaces. The resulting acid etch treated buffered SiO₂ coated InP/ZnS/Se NSs were further dried at or below a temperature of about 60° C. under vacuum for about 60 min to remove substantially all moisture from them. Following the drying of the acid etch treated buffered SiO₂ coated InP/ZnS/Se NSs, they were isolated by precipitation and centrifugation and re-dispersed in toluene or chloroform to form a stable hydrophobic solution.

It should be noted that even though in the above described method TOP was used as a solvent for buffer agent zinc salt (zinc oleate), other organic solvents may be used. For example, inorganic buffer agents such as zinc oleate may be dispersed in ODE (1-octadecene) or a mixture of ODE and TOP. In some embodiments, TPB (tetrabutylphosphine) or DPP (diphenylphosphine) can be used as a solvent for inorganic buffer agents such as metal salts including In, Al, or Mg. In some embodiments, ethanol may be used to dissolve AlCl₃ when Al₂O₃ is used as an inorganic buffer agent. Also, it should be noted that in some embodiments, organo-metallic compounds can be used as inorganic buffer agents. For example, diethyl zinc (DEZ), may be used instead of zinc oleate as described in the above method and hexane, cyclohexane, toluene, ODE, or TOP may be used as a solvent for DEZ.

In some embodiments, the photoluminescence spectrum of the buffered SiO₂ coated InP/ZnS/Se NSs population has a FWHM in a range from about 20 nm and 50 nm, from about 22 nm and 50 nm from about 24 nm and 50 nm, from about 26 nm and 50 nm, from about 28 nm and 50 nm, from about 28 nm and 46 nm, from about 28 nm and 42 nm, from about 20 nm and 36 nm, from about 20 nm and 34 nm, or from about 20 nm and 30 nm.

In some embodiments, the size of the resulting buffered SiO₂ coated InP/ZnS/Se NSs is in a range from about 20 nm to about 50 nm in diameter, from about 24 nm to about 50 nm in diameter, from about 28 nm to about 50 nm in diameter, from about 32 nm to about 50 nm in diameter, from about 35 nm to about 50 nm in diameter, from about 20 nm to about 45 nm in diameter, from about 24 nm to about 45 nm in diameter, from about 30 nm to about 45 nm in diameter, from about 35 nm to about 45 nm in diameter, or from about 25 nm to about 35 nm in diameter. In some embodiments, the average size of the buffered SiO₂ coated InP/ZnS/Se NSs is about 25 nm, about 35 nm, or about 40 nm.

In some embodiments, the thickness of the SiO₂ barrier layer of the buffered SiO₂ coated InP/ZnS/Se NSs is in a range from about 8 nm to about 20 nm, from about 10 nm to about 20 nm, from about 15 nm to about 20 nm, from about 8 nm to about 15 nm, or from about 10 nm to about 15 nm.

In some embodiments, the buffered SiO₂ coated InP/ZnS/Se NSs emit light in the red, orange, and/or yellow range. In some embodiments, the resulting SiO₂ coated NSs have a primary emission peak wavelength between about 605 nm and about 650 nm, between about 615 nm and about 640 nm, between about 620 nm and about 635 nm, or between about 625 nm and about 630 nm.

In some embodiments, the buffered SiO₂ coated InP/ZnS/Se NSs without acid etch treatment display a QY between 40% and 70%, between 45% and 70%, between 50% and 70%, between 40% and 65%, between 40% and 60%, between 40% and 50%, between 45% and 55%, or between 55% and 65%. In some embodiments, the acid etch treated buffered SiO₂ coated InP/ZnS/Se NSs display a QY between 60% and 80%, between 65% and 80%, between 70% and 80%, between 60% and 75%, or between 65% and 75%.

Example Characteristics of SiO₂ Coated InP/ZnS/Se Nanostructures with and without Buffering

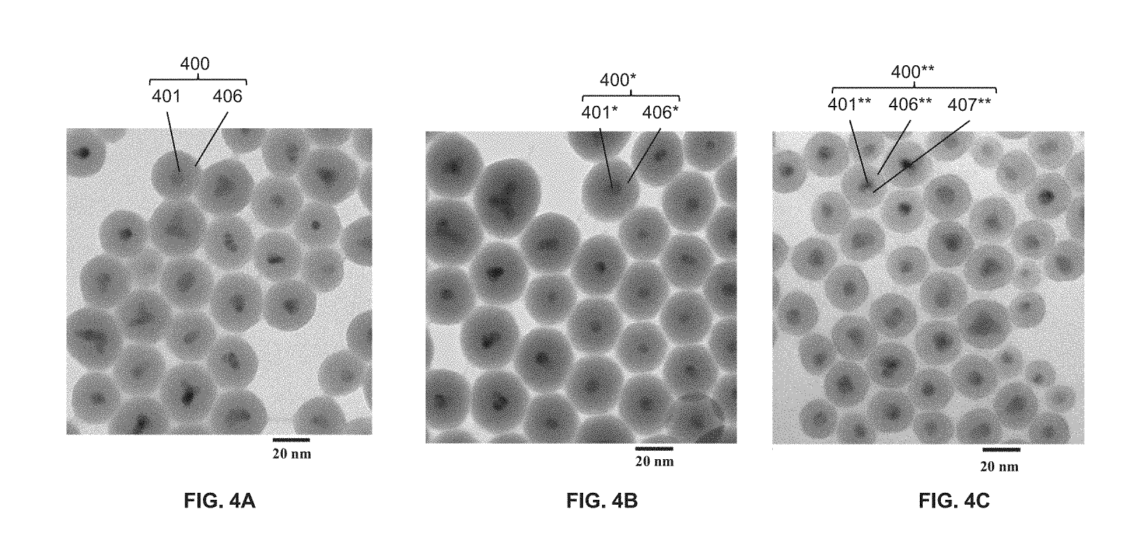

FIG. 4A shows example TEM image of unbuffered SiO₂ coated red InP/ZnS/Se NSs 400 produced by a method similar to the example methods described above. That is, NSs 400 are produced without addition of buffer agent(s) prior to incorporation of precursor and catalysts in reverse micro-micelles as described in example methods above. Each SiO₂ coated red InP/ZnS/Se NSs 400 includes a red InP/ZnS/Se core-shell NS 401 and a SiO₂ barrier layer 406 surrounding the NS 401. The size of the NSs 400 is in a range from about 28 nm to about 35 nm in diameter.

FIG. 4B shows example TEM image of TOP buffered SiO₂ coated red InP/ZnS/Se NSs 400* produced by the example methods described above. That is, NSs 400* are produced with addition of TOP buffer agent prior to incorporation of precursor and catalysts in reverse micro-micelles as described in example methods above. Each SiO₂ coated red InP/ZnS/Se NSs 400* includes a red InP/ZnS/Se core-shell NS 401* and a SiO₂ barrier layer 406* surrounding the NS 401*. The size of the NSs 400* is in a range from about 28 nm to about 35 nm in diameter. Comparison of NSs 400 and 400* shows that their encapsulated NSs 401 and 401* are similar in size and the addition of TOP buffer agent during synthesis of NSs 400* did not form a buffer layer around NSs 401*.

FIG. 4C shows example TEM image of ZnO buffered SiO₂ coated red InP/ZnS/Se NSs 400** produced by the example methods described above. That is, NSs 400** are produced with addition of Zn salt buffer agent prior to incorporation of precursor and catalysts in reverse micro-micelles as described in example methods above. Each SiO₂ coated red InP/ZnS/Se NSs 400** includes a red InP/ZnS/Se core-shell NS 401** and a SiO₂ barrier layer 406** surrounding the NS 401*. Also, FIG. 4C indicates the presence of a ZnO buffer layer 407** and as a result, the core-shell structure of encapsulated NSs 401** appear larger in diameter than NSs 401. The size of the NSs 400** is in a range from about 28 nm to about 35 nm in diameter.

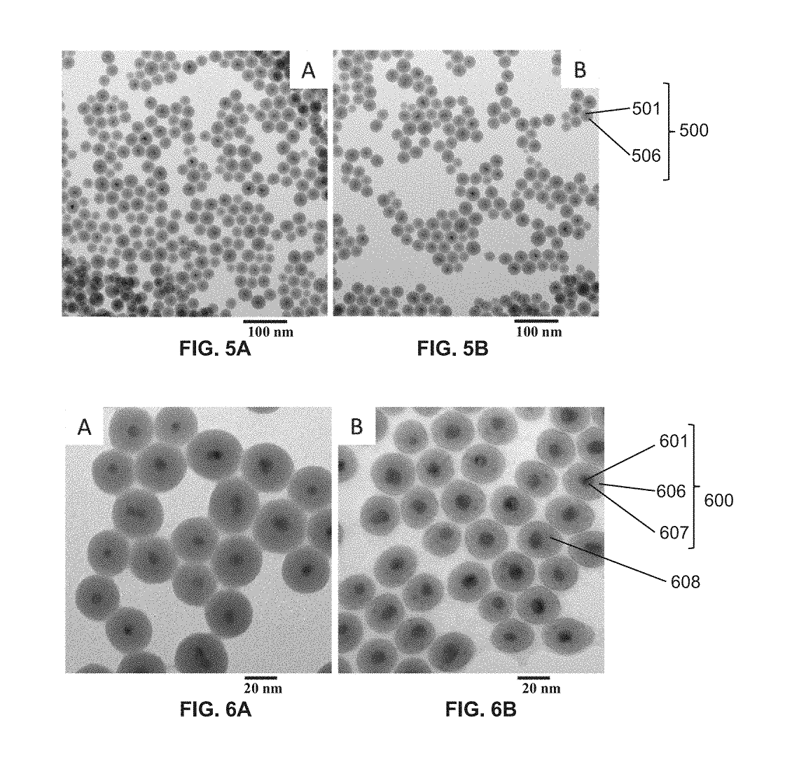

FIGS. 5A-B show example TEM images of unbuffered SiO₂ coated green InP/ZnS/Se NSs and TOP buffered SiO₂ coated green InP/ZnS/Se NSs 500, respectively. NSs 500 are produced with addition of TOP buffer agent prior to incorporation of precursor and catalysts in reverse micro-micelles as described in example methods above. The size of the NSs 500 is in a range from about 28 nm to about 35 nm in diameter. FIGS. 6A-6B show example TEM images of unbuffered SiO₂ coated green InP/ZnS/Se NSs and ZnO buffered SiO₂ coated green InP/ZnS/Se NSs 600, respectively. The size of the NSs 600 is in a range from about 28 nm to about 35 nm in diameter. Similar to NSs 400* and 400** discussed above, FIG. 6B indicates the presence of a ZnO buffer layer 607 in ZnO buffered NSs 600 and not in the TOP buffered NSs 500. FIG. 6B also indicates the presence of ZnO nanoparticles 608 in some of NSs 600.

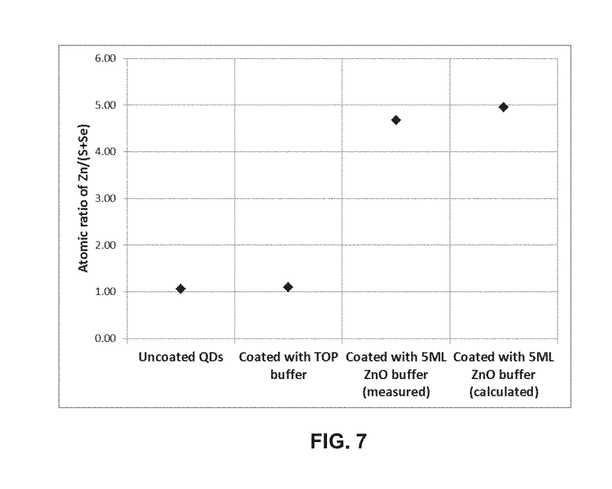

The incorporation of ZnO in ZnO buffered SiO₂ coated InP/ZnS/Se NSs was further evidenced by elemental analysis. FIG. 7 shows a plot of atomic ratio of zinc to sulfur and selenium for uncoated InP/ZnS/Se NSs, TOP buffered InP/ZnS/Se NSs, and ZnO buffered InP/ZnS/Se NSs. ICP-OES (Inductively coupled plasma atomic emission spectroscopy) analysis was performed on uncoated NSs and buffered barrier layer coated NSs. As indicated by FIG. 7, the atomic ratio of zinc to sulfur and selenium increased by about 5 folds after incorporation of 5 monolayer equivalent of ZnO into the ZnO buffered barrier layer coated NSs. The amount of zinc found in the ZnO buffered barrier layer coated NSs is substantially close to the amount of zinc precursor added as buffer agent during synthesis of the ZnO buffered barrier layer coated NSs. This suggests that most of the zinc added as precursor reacted and incorporated into the ZnO buffered barrier layer coated NSs.

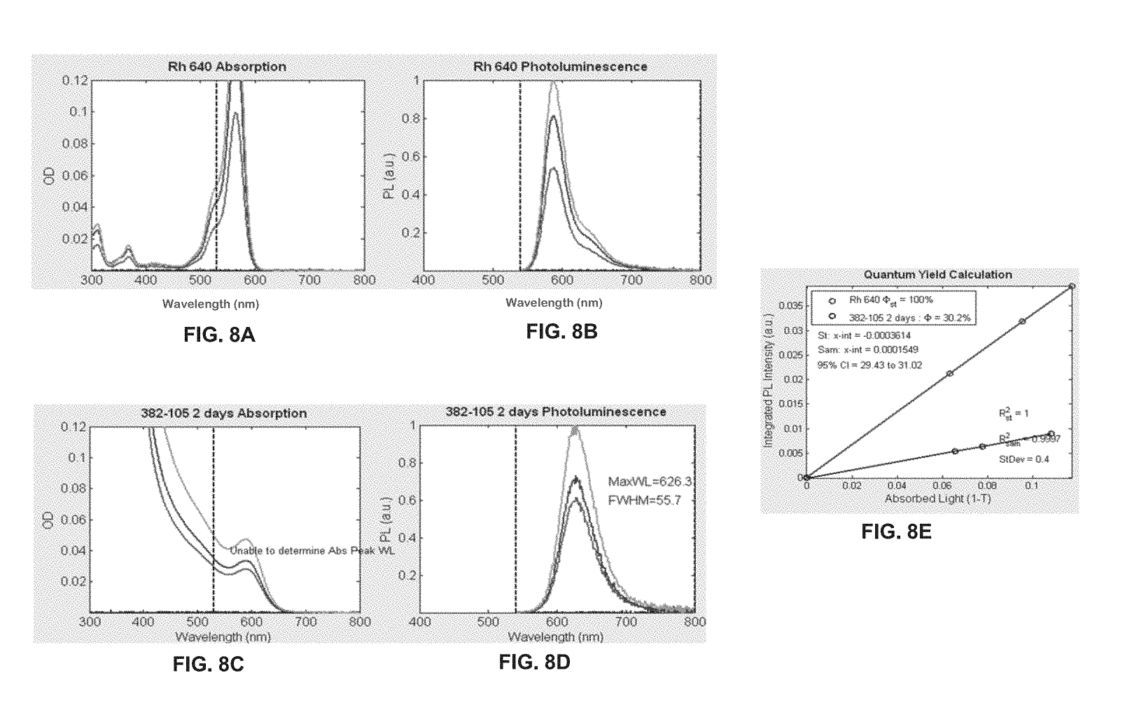

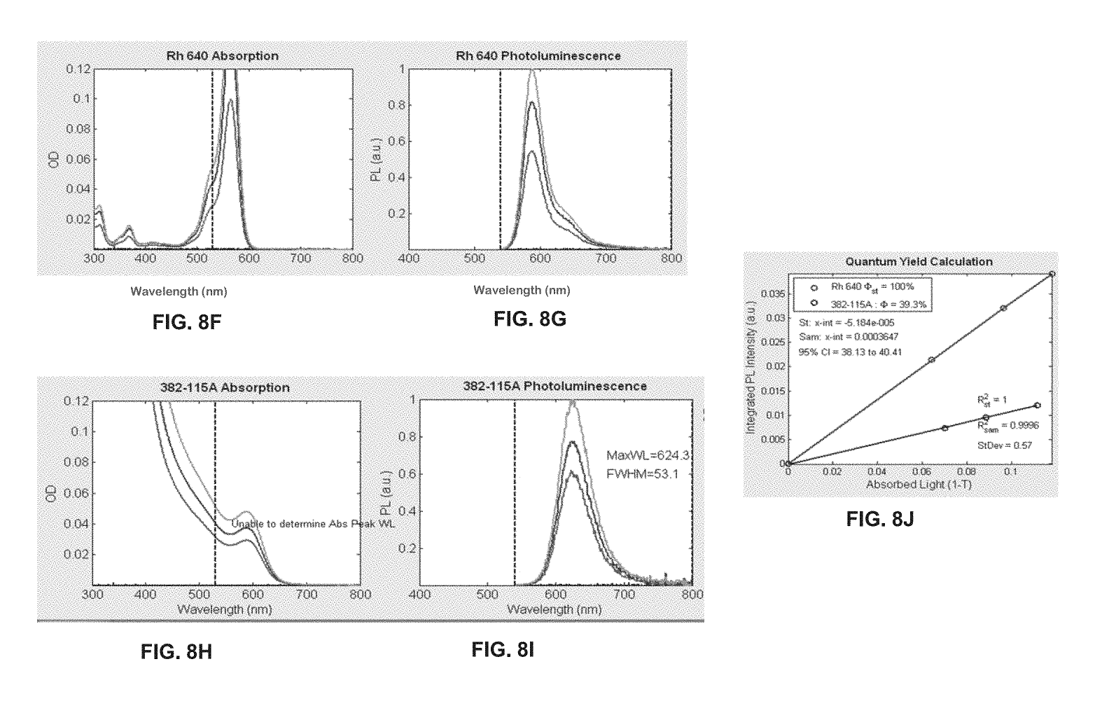

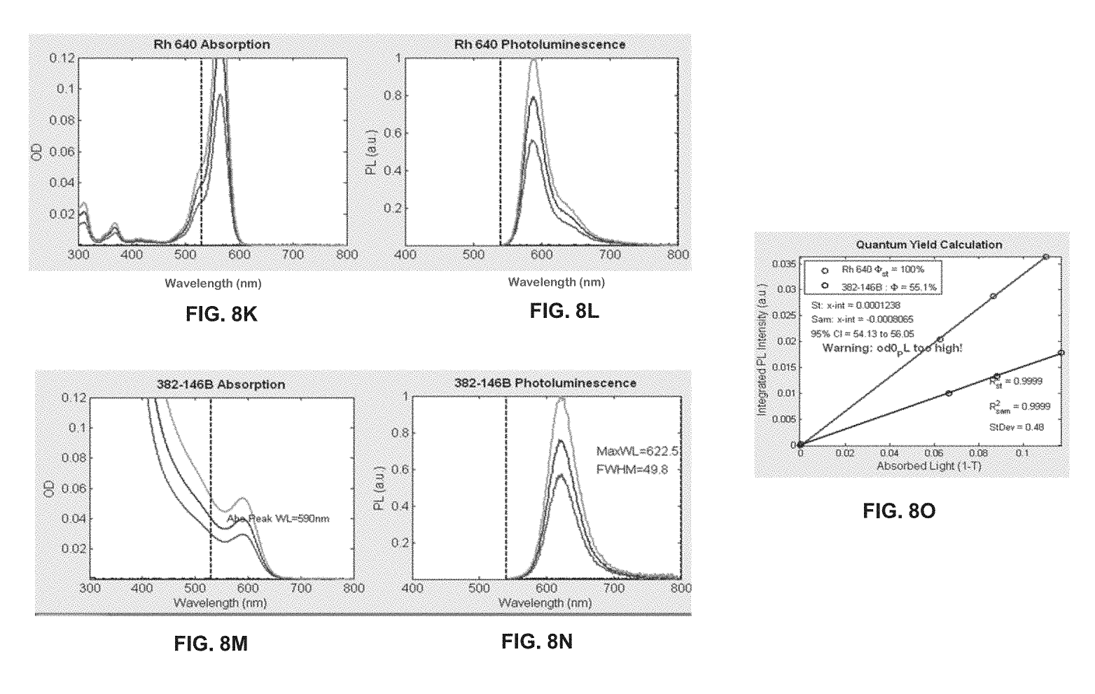

FIGS. 8A-8E show QY calculation of unbuffered SiO₂ barrier layer coated red InP/ZnSe/ZnS NSs in a manner similar to that described with reference to FIGS. 3A-E. In an embodiment, the QY measurement of unbuffered SiO₂ barrier layer coated InP/ZnSe/ZnS NSs for emission in the red region of the visible spectrum is about 30%.

FIGS. 8F-8J show QY calculation of TOP buffered SiO₂ barrier layer coated red InP/ZnSe/ZnS NSs in a manner similar to that described with reference to FIGS. 3A-E. In an embodiment, the QY measurement of TOP buffered SiO₂ barrier layer coated InP/ZnSe/ZnS NSs for emission in the red region of the visible spectrum is about 40%.

FIGS. 8K-8O show QY calculation of ZnO buffered SiO₂ barrier layer coated red InP/ZnSe/ZnS NSs in a manner similar to that described with reference to FIGS. 3A-E. In an embodiment, the QY measurement of ZnO buffered SiO₂ barrier layer coated InP/ZnSe/ZnS NSs for emission in the red region of the visible spectrum is about 55%.

Thus, comparison of QYs from FIGS. 8A-8O indicates that addition of buffer agent(s) during synthesis of barrier layer coated NSs improves the QY of the resulting buffered barrier layer coated NSs, according to various embodiments.

Tables 1 and 2 below present example optical properties of uncoated red and green InP/ZnSe/ZnS NSs, ZnO buffered SiO₂ barrier layer coated red and green InP/ZnSe/ZnS NSs, and acid etch treated ZnO buffered SiO₂ barrier layer coated red and green InP/ZnSe/ZnS NSs, respectively, produced by the example methods described above. As shown in Tables 1 and 2, for both the red and green InP/ZnSe/ZnS NSs, QY reduced after the coating of the InP/ZnSe/ZnS NSs with ZnO buffered SiO₂ barrier layer, but QY increased post acid etch treatment of the ZnO buffered SiO₂ barrier layer coated InP/ZnSe/ZnS NSs.

TABLE 1
Example optical data for red InP/ZnSe/ZnS NSs

| | | Emission | | |
|---|---|---|---|---|
| Sample | | Wavelength | FWHM | QY |
| No. | Description | (nm) | (nm) | (%) |
| 1 | Uncoated InP/ZnSe/ZnS NSs | 640.0 | 50.0 | 73.6 |
| 2 | ZnO buffered SiO₂ | 639.3 | 52.7 | 63.7 |
| | barrier layer coated | | | |
| | InP/ZnSe/ZnS NSs | | | |
| 3 | Acid etch treated | 641.8 | 52.0 | 76.7 |
| | ZnO buffered SiO₂ | | | |
| | barrier layer coated | | | |
| | InP/ZnSe/ZnS NSs | | | |

TABLE 2
Example optical data for green InP/ZnSe/ZnS NSs

| | | Emission | | |
|---|---|---|---|---|
| Sample | | Wavelength | FWHM | QY |
| No. | Description | (nm) | (nm) | (%) |
| 1 | Uncoated InP/ZnSe/ZnS NSs | 530.0 | 41.2 | 79.0 |
| 2 | ZnO buffered SiO₂ | 531.9 | 42.0 | 50.6 |
| | barrier layer coated | | | |
| | InP/ZnSe/ZnS NSs | | | |
| 3 | Acid etch treated | 532.0 | 42.8 | 64.9 |
| | ZnO buffered SiO₂ | | | |
| | barrier layer coated | | | |
| | InP/ZnSe/ZnS NSs | | | |

### Example Steps for Forming Buffered Barrier Layer Coated Core-Shell Nanostructures

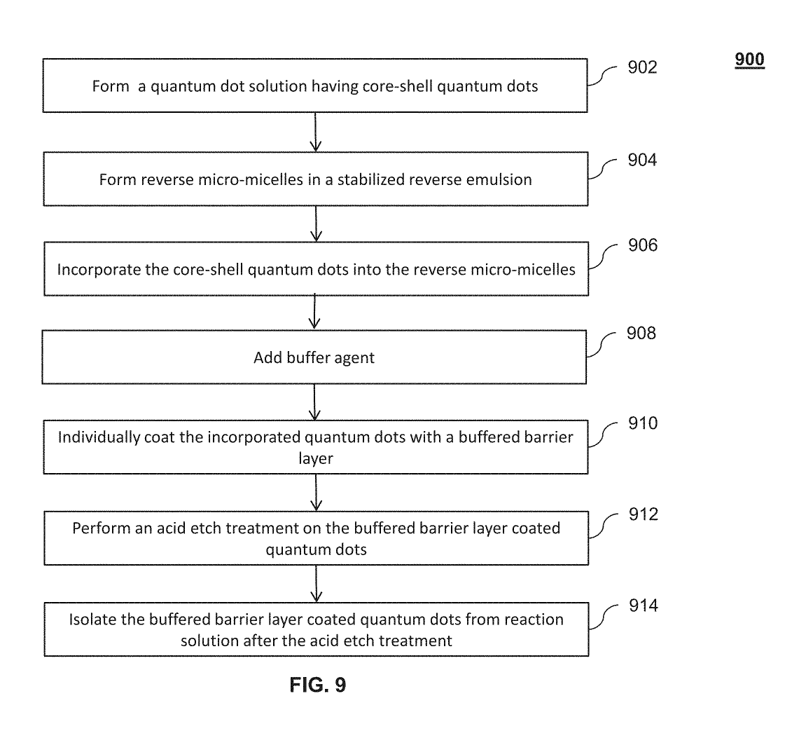

FIG. 9 illustrates a flowchart for making buffered barrier layer coated core-shell NSs, according to an embodiment. Method 900 may be performed to form NSs similar to NSs 100, 200, 400*, 400**, 500, and 600. Method 900 is not intended to be exhaustive and other steps may be performed without deviating from the scope or spirit of the invention. Solely for illustrative purposes, the steps illustrated in FIG. 9 will be described with reference to example processes illustrated in FIGS. 2A-2E. Steps can be performed in a different order or not performed depending on specific applications.

In step 902, a NS solution having core-shell NSs is formed, according to an embodiment. For example, NS solution having core-shell NSs may be produced by dispersing core-shell NSs such as NSs 101 and 201 in a solvent (e.g., cyclohexane, toluene, or hexane).

In step 904, reverse micro-micelles formed in a stabilized reverse emulsion, according to an embodiment. For example, reverse micro-micelles in a stabilized reverse emulsion may be produced by forming a first mixture of one or more surfactants (e.g., IGEPAL CO-520, IGEPAL CO-630, IGEPAL CA-630, Triton X-100, or Brij 53) with hydrophobic solvents such as, but not limited to, cyclopentane, cyclohexane, or cycloheptane and stirring the first mixture for about 20 min.

In step 906, the core-shell NSs are incorporated into the reverse micro-micelles, according to an embodiment. For example, the core-shell NSs are incorporated into the reverse micro-micelles by forming a second mixture of the NS solution and the first mixture and stirring the second mixture for about 20 min.

In step 908, buffer agent is added to the second mixture to form a third mixture, according to an embodiment. For example, an organic buffer agent, such as TOP, diphenylphosphine, tributylphosphine, or other aliphatic phosphines, or an inorganic buffer agent such as metal salts may be added to the second mixture. The third mixture is stirred for about 20 min.

In step 910, the incorporated NSs are individually coated with a barrier layer, according to an embodiment. For example, the incorporated NSs are individually coated with a barrier layer by forming a fourth mixture of one or more precursor solution and the third mixture and stirring the fourth mixture for about 20 min. The formation of fourth mixture is followed by forming a fifth mixture of one or more catalysts and the fourth mixture and stirring the fifth mixture for about 2 min. Following the about 2 min stirring, the bottle including the fifth mixture is capped and stored for 7 days without stirring or heating the fifth mixture.

In step 912, the resulting buffered barrier layer coated NSs are subjected to an acid etch treatment, according to an embodiment. For example, the resulting buffered barrier layer coated NSs are subjected to an acid etch treatment by forming a sixth mixture of one or more acids and the fifth mixture and treating the resulting buffered barrier layer coated NSs in the sixth mixture for about 12 hours.

In step 914, the resulting acid etch treated buffered barrier layer coated NSs are isolated from the sixth mixture, according to an embodiment. For example, the acid etch treated buffered barrier layer coated NSs are isolated by evaporating the solvent, the unreacted precursors, the catalysts, and reaction byproducts at or below a temperature of about 50° C. under vacuum to yield buffered barrier layer coated NSs having surfactants on their outer surfaces similar to, for example, NSs 200 described above. The evaporation is followed by further drying of the acid etch treated buffered barrier layer coated NSs at a temperature of about 60° C. under vacuum for about 60 min to remove substantially all moisture from them. Following the drying, the acid etch treated buffered barrier layer coated NSs are isolated by precipitation and centrifugation.

### An Example Embodiment of a Nanostructure Film

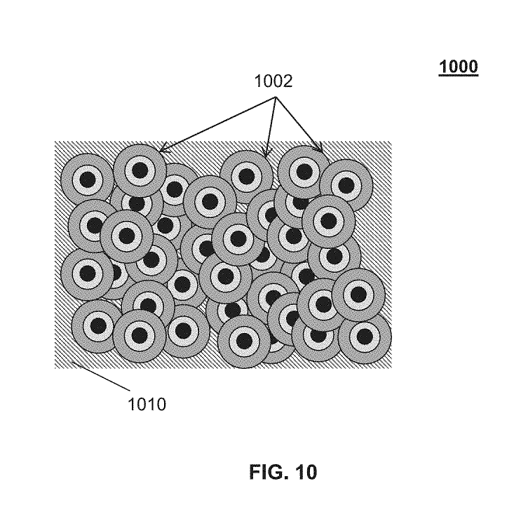

A population of buffered barrier layer coated NSs having NSs such as NSs 100, 200, 400*, 400**, 500, and/or 600 discussed above may be used in a variety of applications that benefit from having sharp, stable, and controllable emissions in the visible and infrared spectrum. Such applications may use the population of buffered barrier layer coated NSs in the form of a NS film 1000 as shown in FIG. 10. In some applications, the light emitting NSs may be cast as a NS film 1000 on a substrate and patterned by a photolithographic process. Display devices such as organic light emitting diode (OLED) display devices or liquid crystal display (LCD) devices may use such a NS film 1000, for example as a color down conversion layer. In such display devices, NS film 1000 may be part of their display panel or pixel units of their display panel and may be disposed on light sources or substrates of the display devices, according to some embodiments.

Typically, non-NS based color down conversion layers in display devices can range from about 1 μm to about 10 μm in thickness. In order to achieve similar or higher optical density and QY from NS based color down conversion layers of similar thickness, such as NS film 1000, a large density of NSs may need to be loaded and closely packed (i.e., adjacent NSs in substantial contact with each other) within NS film 1000 with low levels of aggregation. However, NSs prepared by current methods tend to aggregate and/or reabsorb emission of adjacent NSs when closely packed in a NS film and consequently, due to quenching of their optical properties, suffer from lower QY compared to non-NS based color down conversion layers. In some embodiments, such problems may be overcome by using NS films of buffered barrier layer coated core-shell NSs such as NSs 100, 200, 400*, 400**, 500, and/or 600. The barrier layer reduces aggregation of these NSs and reabsorbing each other's emission and consequently, achieve high optical density and QY even when these NSs are closely packed in a NS film of about 1 μm to about 3 μm. The barrier layer of these NSs also help to protect them from harsh environments (e.g., heat, chemicals) during processing of NS films.

The population of buffered barrier layer coated NSs is optionally embedded in a matrix that forms a film (e.g., an organic polymer, silicon-containing polymer, inorganic, glassy, and/or other matrix). This film may be used in production of a NS phosphor, and/or incorporated into a device, e.g., an LED, backlight, downlight, or other display or lighting unit or an optical filter. Exemplary phosphors and lighting units can, e.g., generate a specific color light by incorporating a population of NSs with an emission maximum at or near the desired wavelength or a wide color gamut by incorporating two or more different populations of NSs having different emission maxima. A variety of suitable matrices are known in the art. See, e.g., U.S. Pat. No. 7,068,898 and U.S. Patent Application Publication Nos. 2010/0276638, 2007/0034833, and 2012/0113672. Exemplary NS phosphor films, LEDs, backlighting units, etc. are described, e.g., in U.S. Patent Application Publications Nos. 2010/0276638, 2012/0113672, 2008/0237540, 2010/0110728, and 2010/0155749 and U.S. Pat. Nos. 7,374,807, 7,645,397, 6,501,091, and 6,803,719.

FIG. 10 illustrates a cross-sectional view of a NS film 1000, according to an embodiment. NS film 1000 may include a plurality of buffered barrier layer coated core-shell NSs 1002 and a matrix material 1010, according to an embodiment. NSs 1002 may be similar to NSs 100, 200, 400*, 400**, 500, and/or 600 in structure, function, and/or characteristics and may be embedded or otherwise disposed in matrix material 1010, according to some embodiments. As used herein, the term “embedded” is used to indicate that the NSs are enclosed or encased within matrix material 1010 that makes up the majority component of the matrix. It should be noted that NSs 1002 may be uniformly distributed throughout matrix material 1010 in an embodiment, though in other embodiments NSs 1002 may be distributed according to an application-specific uniformity distribution function. It should be noted that even though NSs 1002 are shown to have the same size in diameter, a person skilled in the art would understand that NSs 1002 may have a size distribution.

In an embodiment, NSs 1002 may include a homogenous population of NSs having sizes that emit in the blue visible wavelength spectrum, in the green visible wavelength spectrum, or in the red visible wavelength spectrum. In other embodiments, NSs 1002 may include a first population of NSs having sizes that emit in the blue visible wavelength spectrum, a second population of NSs having sizes that emit in the green visible wavelength spectrum, and a third population of NSs that emit in the red visible wavelength spectrum.

Matrix material 1010 may be any suitable host matrix material capable of housing NSs 1002. Suitable matrix materials may be chemically and optically compatible with NSs 1002 and any surrounding packaging materials or layers used in applying NS film 1000 to devices. Suitable matrix materials may include non-yellowing optical materials which are transparent to both the primary and secondary light, thereby allowing for both primary and secondary light to transmit through the matrix material. In an embodiment, matrix material 1010 may completely surround each of the NSs 1002. The matrix material 1010 may be flexible in applications where a flexible or moldable NS film 1000 is desired. Alternatively, matrix material 1010 may include a high-strength, non-flexible material.

In another embodiment, matrix material 1010 may have low oxygen and moisture permeability, exhibit high photo- and chemical-stability, exhibit favorable refractive indices, and adhere to outer surfaces of NSs 1002, thus providing an air-tight seal to protect NSs 1002. In another embodiment, matrix material 1010 may be curable with UV or thermal curing methods to facilitate roll-to-roll processing.

Matrix material 1010 may include polymers and organic and inorganic oxides. Suitable polymers for use in matrix material 1010 may be any polymer known to the ordinarily skilled artisan that can be used for such a purpose. The polymer may be substantially translucent or substantially transparent. Matrix material 1010 may include, but not limited to, epoxies, acrylates, norbornene, polyethylene, poly(vinyl butyral):poly(vinyl acetate), polyurea, polyurethanes; silicones and silicone derivatives including, but not limited to, amino silicone (AMS), polyphenylmethylsiloxane, polyphenylalkylsiloxane, polydiphenylsiloxane, polydialkylsiloxane, silsesquioxanes, fluorinated silicones, and vinyl and hydride substituted silicones; acrylic polymers and copolymers formed from monomers including, but not limited to, methylmethacrylate, butylmethacrylate, and laurylmethacrylate; styrene-based polymers such as polystyrene, amino polystyrene (APS), and poly(acrylonitrile ethylene styrene) (AES); polymers that are crosslinked with bifunctional monomers, such as divinylbenzene; cross-linkers suitable for cross-linking ligand materials, epoxides which combine with ligand amines (e.g., APS or PEI ligand amines) to form epoxy, and the like.

In some embodiments, matrix material 1010 includes scattering microbeads such as TiO₂ microbeads, ZnS microbeads, or glass microbeads that may improve photo conversion efficiency of NS film 1000.

According to some embodiments, NS film 1000 may be formed by mixing NSs 1002 in a polymer (e.g., photoresist) and casting the NS-polymer mixture on a substrate, mixing NSs 1002 with monomers and polymerizing them together, mixing NSs 1002 in a sol-gel to form an oxide, or any other method known to those skilled in the art.

### Example Embodiments of a NS Film Based Display Device

The invention also provides a display device comprising:
(a) a layer that emits radiation;
(b) a film layer comprising a population of buffered barrier layer coated NSs, disposed on the radiation emitting layer; and
(c) an optical element, disposed on the barrier layer.

In one embodiment, the radiation emitting layer, the film layer, and the optical element are part of a pixel unit of the display device. In another embodiment, the optical element is a color filter.

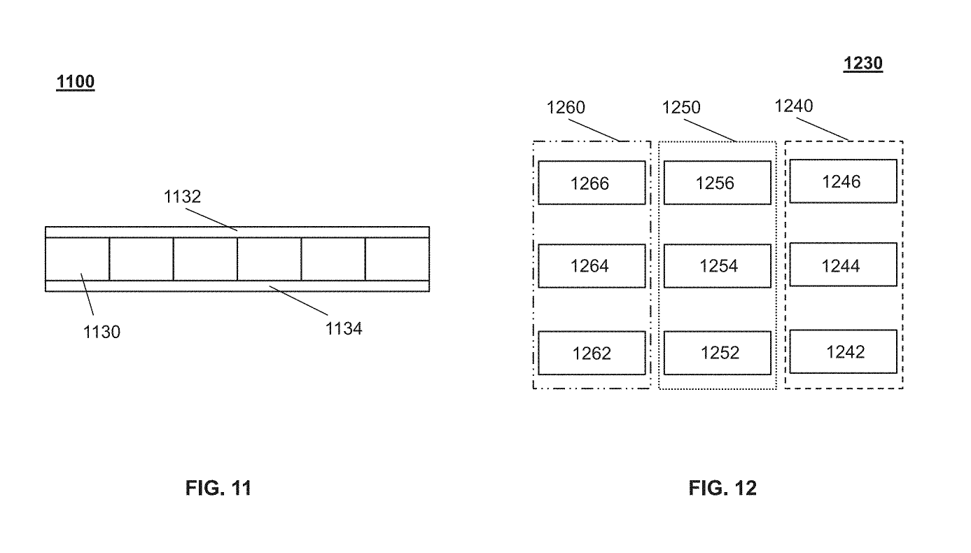

FIG. 11 illustrates a schematic of an exploded cross-sectional view of a display panel 1100 of a display device, according to an embodiment. In some embodiments, the display device is an OLED display device or LCD device. Display panel 1100 may include a plurality of pixel units 1130, a transmissive cover plate 1132, and a back plate 1134, according to an example of this embodiment. Even though FIG. 11 shows display panel 1100 having few pixel units 1130, a skilled person would understand that display panel 1100 of a display device may include an one or two dimensional array of pixel units and any number of pixel units without departing from the general concept of the present invention.

The cover plate 1132 may serve as an optically transparent substrate on which other components (e.g., electrode) of the display device may be disposed and/or may act as an optically transparent protective cover for pixel units 1130. In some embodiments, pixel units 1130 may be tri-chromatic having red, green, and blue sub-pixel units. In some embodiments, pixel units 1130 may be monochromatic having either red, green, or blue sub-pixel units. In some embodiments, display panel 1100 may have a combination of both tri-chromatic and monochromatic pixel units 1130. In some embodiments, pixel units 1130 may have two or more sub-pixel units.

Typically, pixel units in display panels have a light source and color filters and light emitted from these pixel units are produced by color filtering of white light sources to produce red, green, and blue pixels in a display device. However, the use of color filters is not an energy efficient process as undesired wavelengths, i.e., light energies are filtered out. Current display devices have used NS films as a color down conversion film in pixel units to reduce the loss of light energy due to filtering. NSs have a very broad absorption characteristics below their emission wavelength, and as a result may absorb and convert many of the wavelengths radiating from the light source to the desired wavelength of the pixel unit. One of the disadvantages of current NS based display devices is that the high optical density and high QY are not achieved with thin NS films of few micrometers or less. The NSs tend to aggregate if they are closely packed in thin NS films as discussed above. Such disadvantages are overcome with the use NS films such as NS film 1000 including buffered barrier layer coated NSs such as NSs 100, 200, 400*, 400**, 500, and/or 600, discussed above, as color down conversion film in pixel units of display devices.

FIG. 12 illustrates an exploded cross-sectional view of a tri-chromatic pixel unit 1230 of a display panel of a display device, according to an embodiment. In some embodiments, the display device is an OLED display device or LCD device. In an example, pixel unit 1230 may be similar to pixel unit 1130 and may be implemented as part of display panel 1100. In another example, at least one of the pixel units 1130 may have a configuration similar to pixel unit 1230. Pixel unit 1230 may include a red sub-pixel unit 1240, a green sub-pixel unit 1250, and a blue sub-pixel unit 1260. Red sub-pixel unit 1240 may include a white or blue light source 1242, a NS film 1244 including red-emitting NSs (e.g., NSs 100, 200, 400*, 400**) disposed on an emitting surface of the light source 1242, and an optically transparent substrate 1246. In some embodiments, light source 1242 and NS film 1244 are substantially in contact with each other. As the red-emitting NSs of NS film 1244 may absorb substantially all wavelengths (i.e., substantially all light energy) radiating from the light source 1242, the use of a red color filter to block out non-red wavelengths radiating from the light source may be eliminated in red sub-pixel unit 1240, according to an embodiment. In some embodiments, the white light source 1242 is a white OLED or a white LED. The white OLED may include an organic layer configured to emit white light.

Green sub-pixel unit 1250 may include a white or blue light source 1252, a NS film 1254 including green-emitting NSs (e.g., NSs 100, 200, 500, 600) disposed on an emitting surface of the light source 1252, and a green color filter 1256. In some embodiments, light source 1252 and NS film 1254 are substantially in contact with each other and NS film 1254 and filter 1256 are substantially in contact with each other. The green-emitting NSs of NS film 1254 may absorb substantially all wavelengths smaller and pass substantially all wavelengths higher than their emission wavelength radiating from the light source 1252. As such, a green color filter 1256 may be used in green sub-pixel unit 1250 to filter out the higher wavelengths (e.g., wavelength corresponding to red light), according to an embodiment. In some embodiments, the white light source 1252 is a white OLED or a white LED.

Blue sub-pixel unit 1260 may include a white light source 1262, an optically transparent substrate 1264 and a blue color filter 1266. A blue color filter 1266 may be used in blue sub-pixel unit 1260 to filter out wavelengths radiating from the light source that are higher than blue emission wavelength (e.g., wavelengths corresponding to red and/or green light), according to an embodiment. In an embodiment, the white light source is a white OLED. In an alternate embodiment, blue sub-pixel unit 1260 may include a UV light source 1262, a NS film 1254 including blue-emitting NSs (e.g., NSs 100, 200) disposed on an emitting surface of the light source 1262, and a blue color filter 1266. In some embodiments, light source 1262 and NS film 1264 are substantially in contact with each other and NS film 1264 and filter 1266 are substantially in contact with each other. The blue-emitting NSs of NS film 1264 may absorb substantially all wavelengths smaller and pass substantially all wavelengths higher than their emission wavelength radiating from the light source 1262. As such, a blue color filter 1266 may be used in blue sub-pixel unit 1260 to filter out the higher wavelengths (e.g., wavelengths corresponding to red and/or green light), according to an embodiment. In some embodiments, the UV light source is a UV LED.

The invention also provides a NS based LED comprising a light source unit, a film layer comprising a population of buffered barrier layer coated NSs such as NSs 100, 200, 400*, 400**, 500, and/or 600 disposed on the light source unit, and an optical element disposed on the film layer, according to an embodiment. The light source unit may be configured to emit light at a primary emission peak wavelength smaller than a primary emission peak wavelength emitted by the population of buffered barrier layer coated NSs.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications of such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A population of buffered barrier layer coated nanostructures comprising:
a nanostructure;
an optically transparent buffer layer disposed on the nanostructure; and
an optically transparent buffered barrier layer, disposed on the buffer layer, configured to provide a spacing between adjacent nanostructures in the population of buffered barrier layer coated nanostructures to reduce aggregation of the adjacent nanostructures.

2. The population of buffered barrier layer coated nanostructures of claim 1, wherein the optically transparent buffer layer comprises an oxide.

3. The population of buffered barrier layer coated nanostructures of claim 1, wherein the optically transparent buffer layer comprises a metal oxide.

4. The population of buffered barrier layer coated nanostructures of claim 1, wherein the optically transparent buffer layer comprises transparent conductive oxides AZO, GZO, IZO, FTO, ITO, or a combination thereof.

5. The population of buffered barrier layer coated nanostructures of claim 1, wherein the optically transparent buffered barrier layer is hydrophobic.

6. The population of buffered barrier layer coated nanostructures of claim 1, wherein the spacing is equal or greater than a Forster radius between adjacent buffered barrier layer coated nanostructures.

7. The population of buffered barrier layer coated nanostructures of claim 1, wherein the nanostructure comprises a core-shell structure having a core and a shell surrounding the core.

8. The population of buffered barrier layer coated nanostructures of claim 1, wherein:
the core comprises a first material;
the shell comprises a second material;
the optically transparent buffer layer comprises a third material;
the optically transparent buffered barrier layer comprises a fourth material; and
the first, second, and third materials are different from each other.

9. The population of buffered barrier layer coated nanostructures of claim 1, wherein the optically transparent buffered barrier layer comprises an oxide.

10. The population of buffered barrier layer coated nanostructures of claim 1, wherein the optically transparent buffered barrier layer comprises silicon dioxide.

11. The population of buffered barrier layer coated nanostructures of claim 1, further comprising surfactants or ligands bonded to the optically transparent buffered barrier layer.

12. The population of buffered barrier layer coated nanostructures of claim 1, having a quantum yield between about 50% to about 70%.

13. The population of buffered barrier layer coated nanostructures of claim 1, having a quantum yield between about 55% to about 65%.

14. The population of buffered barrier layer coated nanostructures of claim 1, having a quantum yield between about 65% to about 80%.

15. The population of buffered barrier layer coated nanostructures of claim 1, wherein the buffered barrier layer coated nanostructure in the population of buffered barrier layer coated nanostructures has an average size ranging from about 20 nm and to about 40 nm in diameter.

16. The population of buffered barrier layer coated nanostructures of claim 1, wherein the buffered barrier layer coated nanostructure in the population of buffered barrier layer coated nanostructures has an average size ranging from about 25 nm and to about 35 nm in diameter.

17. The population of buffered barrier layer coated nanostructures of claim 1, wherein the optically transparent buffered barrier layer has a thickness ranging from about 8 nm and to about 20 nm in diameter.

18. The population of buffered barrier layer coated nanostructures of claim 1, wherein the nanostructures are quantum dots.

19. A method of making a population of buffered barrier layer coated nanostructures, the method comprising:
forming a solution of reverse micro-micelles using surfactants;
incorporating nanostructures into the reverse micro-micelles;
incorporating a buffer agent into the reverse micro-micelles;
individually coating the nanostructures with a buffered barrier layer to form the buffered barrier layer coated nanostructures; and
isolating the buffered barrier layer coated nanostructures with the surfactants of the reverse micro-micelles disposed on the barrier layer.

20. The method of claim 19, wherein the incorporating of the nanostructures into the reverse micro-micelles comprises forming a first mixture of the nanostructures and the solution of reverse micelles.

21. The method of claim 19, wherein the incorporating of the buffer agent into the reverse micro-micelles comprises forming a second mixture of the buffer agent and the first mixture.

22. The method of claim 19, wherein the individually coating of the nanostructures with a buffered barrier layer includes:
forming a third mixture of a precursor and the second mixture; and
forming a fourth mixture of a catalyst and the third mixture.

23. The method of claim 19, wherein the isolating of the buffered barrier layer coated nanostructures includes heating the fourth mixture at or below a temperature of about 50° C. under vacuum.

24. The method of claim 19, wherein the buffer agent comprises an organic or an inorganic material.

25. The method of claim 19, wherein the buffer agent comprises a metal salt.

26. The method of claim 19, further comprises forming a buffer layer in substantial contact with the nanostructures incorporated into the reverse micro-micelles.

27. The method of claim 19, wherein the buffer layer comprises an oxide.

28. The method of claim 19, wherein the buffer layer comprises a metal oxide.

29. A nanostructure film comprising:
a population of buffered barrier layer coated nanostructures comprising:
a nanostructure,
an optically transparent buffer layer disposed on the nanostructure, and
an optically transparent buffered barrier layer, disposed on the buffer layer, configured to provide a spacing between adjacent nanostructures in the population of buffered barrier layer coated nanostructures to reduce aggregation of the adjacent nanostructures; and
a matrix material configured to house the population of buffered barrier layer coated nanostructures and be in contact with the optically transparent buffered barrier layer.

30. A display device comprising:
a layer that emits radiation;
a film layer, comprising a population of buffered barrier layer nanostructures, disposed on the radiation emitting layer, wherein the population of buffered barrier layer nanostructures comprises:
a nanostructure,
an optically transparent buffer layer disposed on the nanostructure, and
an optically transparent buffered barrier layer, disposed on the buffer layer, configured to provide a spacing between adjacent nanostructures in the population of buffered barrier layer coated nanostructures to reduce aggregation of the adjacent nanostructures; and
an optical element disposed on the film layer.

31. The display device of claim 28, wherein the radiation emitting layer, the film layer, and the optical element are part of a pixel unit of the display device.

32. The display device of claim 28, wherein the optical element is a color filter.

33. A light emitting diode (LED) device comprising:
a light source unit;
a film layer, comprising a population of buffered barrier layer nanostructures, disposed on the light source unit, wherein the population of buffered barrier layer nanostructures comprises:
a nanostructure,
an optically transparent buffer layer disposed on the nanostructure, and
an optically transparent buffered barrier layer, disposed on the buffer layer, configured to provide a spacing between adjacent nanostructures in the population of buffered barrier layer coated nanostructures to reduce aggregation of the adjacent nanostructures; and
an optical element disposed on the film layer.

34. A method of making a population of buffered barrier layer coated nanostructures, the method comprising:
forming a solution of reverse micro-micelles using surfactants;
incorporating nanostructures into the reverse micro-micelles;
incorporating a buffer agent into the reverse micro-micelles;
individually coating the nanostructures with a buffered barrier layer to form the buffered barrier layer coated nanostructures; and
performing an acid etch treatment of the buffered barrier layer coated nanostructures.

35. The method of claim 34, further comprising isolating the buffered barrier layer coated nanostructures with the surfactants of the reverse micro-micelles disposed on the barrier layer after the performing of the acid etch treatment.

36. The method of claim 34, wherein the incorporating of the nanostructures into the reverse micro-micelles comprises forming a first mixture of the nanostructures and the solution of reverse micelles.

37. The method of claim 34, wherein the incorporating of the buffer agent into the reverse micro-micelles comprises forming a second mixture of the buffer agent and the first mixture.

38. The method of claim 34, wherein the individually coating of the nanostructures with a buffered barrier layer includes:
forming a third mixture of a precursor and the second mixture; and
forming a fourth mixture of a catalyst and the third mixture.

39. The method of claim 34, wherein the performing of the acid etch treatment of the buffered barrier layer nanostructures comprises forming a sixth mixture of an acid and the fourth mixture.

40. The method of claim 34, wherein the performing of the acid etch treatment of the buffered barrier layer nanostructures comprises:
selectively removing the catalyst; and
forming a sixth mixture of an acid and the fourth mixture.

41. The method of claim 34, wherein the acid comprises acetic acid, hydrochloric acid, nitric acid, or a fatty acid.
